(19) United States
(12) Patent Application Publication
(10) Pub. No.: US 2007/0090485 A1
(43) Pub. Date: Apr. 26, 2007

(54) Semiconductor device and method of manufacturing the same

(75) Inventor: Yoshihiro Takao, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/362,084

(22) Filed: Feb. 27, 2006

(30) Foreign Application Priority Data
Oct. 21, 2005 (JP) 2005-307175

(51) Int. Cl. H01L 29/00; H01L 21/336

(52) U.S. Cl. 257/510; 438/296; 257/E29.02

(57) ABSTRACT

Provided is a semiconductor device including: a p-type silicon substrate; a p-well which is formed in the silicon substrate, and which has a planar shape with no hole; an n-well integrally formed, in the silicon substrate, in a planar shape obtained by inverting the pattern of the p-well; a first and a second gate electrodes formed respectively on the two wells; an n-type source/drain region formed in the p-well beside the first gate electrode; a p-type impurity diffusion region for well contact which is formed in the p-well, and to which a first substrate bias voltage is applied; a p-type source/drain region formed in the n-well beside the second gate electrode; and an n-type impurity diffusion region for well contact which is formed in the n-well, and to which a second substrate bias voltage is applied.

### CROSS-REFERENCE TO RELATED APPLICATIONS

This application is based on and claims priority of Japanese Patent Application No. 2005-307175 filed on Oct. 21, 2005, the entire contents of which are incorporated herein by reference.

### BACKGROUND OF THE INVENTION

1. Field of the Invention

The present invention relates to a semiconductor device and a method of manufacturing a semiconductor device.

2. Description of the Related Art

In recent years, semiconductor devices such as LSI have been constructed in increasingly smaller size. As a result, gate lengths in MOS transistors formed in the semiconductor devices become smaller and smaller. Such a miniaturization is advantageous for constructing electronic appliances in smaller size. On the contrary, variation in gate lengths, which stems from patterning errors, amplifies variation of MOS transistor characteristics such as variation of the operation speed. Suppose that, for example, an intended gate length is 0.1 μm and a finally-obtained gate length is longer than the intended gate length, for example, 1.2 μm. This decreases a source-drain current, and causes the MOS transistor to malfunction in a worst case.

For the purpose of preventing such variation in characteristics, for example, the source-drain current is caused to have a designed value by means of applying a substrate bias voltage to the well of the MOS transistor. A gate length does not vary from a MOS transistor to another at random. Variation in gate length occurs in all of the MOS transistors with the same tendency. For example, a gate length is larger than a designed value in all of the MOS transistors. For this reason, characteristics of these MOS transistors can be caused to have designed values by means of applying a substrate bias voltage commonly to the wells of the MOS transistors of the same conduction type, instead of applying the substrate bias voltage individually to all of the MOS transistors.

In the case where a p-type silicon substrate is used as a semiconductor substrate, a plurality of p-wells are electrically connected with one another through the p-type silicon substrate. Therefore, a special structure for applying a common substrate bias voltage to each of the p-wells is unnecessary.

However, a plurality of n-wells which are formed like islands in the p-type silicon substrate have a structure in which the plurality of n-wells are surrounded by the p-type silicon substrate. Therefore, a structure for electrically connecting the n-wells with one another is needed to apply a common substrate bias voltage to each of the n-wells.

Structures generally used for this purpose includes such a structure in which a common deep n-well is formed underneath a plurality of n-wells close to the upper surface of the silicon substrate so that the plurality of n-wells are electrically connected with one another through the deep n-well. Deep n-wells of this kind are disclosed in Japanese Patent Laid-open Official Gazettes No. Hei. 10-199993 and No. 2002-198439.

Deep n-wells of this kind are formed deeper in the silicon substrate than usual n-wells closer to the upper surface of the silicon substrate. For this reason, the acceleration energy used in the ion implantation for the deep n-wells is set at approximately 1 MeV, which is considerably higher than usual (several hundred keV). However, since ion implanters cannot produce a larger beam current while producing a larger acceleration energy, ion implanters have to produce a smaller beam current while deep n-wells are being formed.

If, however, a smaller beam current is used in this manner, it takes vast time to implant ions in the case where the dose (concentration of impurities) is increased in order to cause the deep n-wells to have a lower resistance. This decreases throughput of the process of manufacturing semiconductor devices to a large extent. For this reason, the dose in the deep n-wells has to be smaller than that in the usual n-wells formed closer to the upper surface of the substrate. As a result, the deep n-wells have a higher resistance. Consequently, a voltage drop is conspicuous in the deep n-wells. This makes it difficult to apply the substrate bias voltage evenly to the plurality of n-wells connected to each of the deep n-wells.

Furthermore, in the case where the deep n-wells are formed by ion implantation, ions (n-type impurities) are introduced into the silicon substrate through resist windows while the p-well forming regions of the silicon substrate are covered with a resist pattern (not shown). At this time, for the purpose of preventing ion channeling, the ions are implanted in a direction different from a direction normal to the silicon substrate.

If, however, ions accelerated with a higher acceleration energy are implanted from tilted direction, the ions collide against side surfaces of the aforementioned resist windows. As a result, ions whose kinetic energy is reduced though reflecting off the side surfaces are introduced into surface layer of channel region of the MOS transistor. Consequently, the characteristics of the MOS transistors vary considerably. Such an effect is called as a well-proximity effect. Countermeasures against the well-proximity effect is examined in the internet site, http://www. eigroup.org/CMC/minutes/121604 presentations/tsmc proposal well prox cmc 1129.ppt, titled “Well-Proximity Effect” by Taiwan Semiconductor Manufacturing Company.

FIG. 1 is a graph showing how threshold voltages Vth respectively of a p-type MOS transistor and an n-type MOS transistor change due to this well-proximity effect. This graph was obtained by using a sample as shown by the plan view in FIG. 1. The sample was obtained by forming source/drain regions 3 and a gate electrode 2 on a silicon substrate 1 as well as thereafter forming, on the resultant silicon substrate 1, a resist pattern 4 having a resist window 4a through which a well forming region is exposed.

The axis of abscissa in FIG. 1 indicates a distance D between the source/drain region 3 and the resist window 4a. In addition, the axis of ordinate in FIG. 1 indicates changed amounts ΔVth which occur respectively in threshold voltages Vth of the MOS transistors in the case where the aforementioned distance D is infinite is defined as a reference.

As is clear from FIG. 1, the smaller the distance D becomes, the larger the changed amounts ΔVth become.

For the purpose of avoiding such a well-proximity effect, the aforementioned distance D has to be made longer by means of enlarging the planar size of a deep n-well. However, if the plan size is enlarged, miniaturization of the element is prevented. Therefore, the enlargement of the plan size is not preferable.

Moreover, technologies related with the present invention are also disclosed in Japanese Patent Laid-open Official Gazette No. Sho. 62-277747.

According to the Japanese Patent Laid-open Official Gazette No. Sho. 62-277747, double-gate MOS (XMOS) transistors are formed on a silicon-on-insulator (SOI) substrate, and low-resistance regions each for shielding a channel region, which are made of polysilicon, are used as interconnects. In this structure, a voltage similar to the substrate bias voltage is applied to back gates, and thus the characteristics of the transistors are controlled.

In this structure, however, fine pattern is required for the back gates. In addition, many steps are required. Accordingly, this complicates the process, and increases manufacturing costs.

### SUMMARY OF THE INVENTION

According to one aspect of the present invention, there is provided a semiconductor device comprising: a semiconductor substrate of a first conduction type; a first conduction type well formed in the semiconductor substrate, where an inside of an outline of the first conduction type well being integral planar shape; a second conduction type well formed in the semiconductor substrate and having an integral planar shape obtained by inverting a planar shape of the first conduction type well; a first and a second gate electrodes formed on the first and second conduction type wells respectively with a gate insulating film interposed therebetween; a second conduction type source/drain region formed in the first conduction type well beside the first gate electrode; a first conduction type impurity diffusion region for well contact, which is formed at a distance from the second conduction type source/drain region in the first conductive type well and is to be applied with a first substrate bias voltage; a first conduction type source/drain region formed in the second conduction type well beside the second gate electrode; a second conduction type impurity diffusion region for well contact, which is formed at a distance from the first conduction type source/drain region in the second conduction type well and is to be applied with a second substrate bias voltage.

According to the present invention, the first conduction type well has a planar shape with no hole, that is, a planar shape whose inside surrounded by the outline is integral. Furthermore, the second conduction type well is formed in a planar shape which is obtained by inverting the pattern of the first conduction type well. Therefore, the second conduction type well is not separated by the first conduction type well, and is accordingly formed integrally. Consequently, there arises no need to form a deep well for electrically connecting the separated second conduction type wells, which in turn reduces the well-proximity effect that is frequently observed when forming the deep well. As a result, it is made possible to suppress the variation in the threshold voltage of the MOS transistor from the designed value which would otherwise arises due to the well-proximity effect, and thus a highly reliable semiconductor device can be provided.

According to the another aspect of the present invention, there is provided a semiconductor device comprising: a silicon-on-insulator (SOI) substrate formed by sequentially laminating a first conduction type support base, an embedded insulating film, and a silicon layer; a fist conduction type impurity diffusion region for well contact which is formed in the support base and is to be applied with a first substrate bias voltage; second conduction type well formed at a distance from the fist conduction type impurity diffusion region in the support base and having a integral planar shape; a second conduction type impurity diffusion region for well contact which is formed in the second conduction type well and is to be applied with a second a second substrate bias voltage; a first gate electrode, formed on a region of the silicon layer where the second conduction type well is not formed, with a gate insulating film interposed therebetween; a second gate electrode formed on the silicon layer located over the second conduction type well with a gate insulating film interposed therebetween; a second conduction type source/drain region formed in the silicon layer beside the first gate electrode; and a first conduction type source/drain region formed in the silicon layer beside the second gate electrode.

According to the present invention, the first conduction type well is not formed in the support base, and only the second conduction type well is formed in the support base. The second conduction type well is formed integrally, so that the second conduction type well is not separated into different portions. Therefore, a deep well for electrically connecting the separated portions of the second conduction type well is not needed. In addition, since the first conduction type well is not formed, the manufacturing process of the semiconductor device is shortened by the fabrication of the first conduction type well. This makes it possible to reduce the costs for manufacturing the semiconductor device.

It should be noted that the first conduction type well may be formed in a region of the support base where the second conduction type well is not formed without minding the manufacturing cost. In this case, the planar shape of the first conduction type well becomes a pattern with no hole obtained by inverting the pattern of the first conduction type well.

Furthermore, the first and second conduction type well have a function similar to a back gate which applies a substrate bias voltage to a channel region from the substrate. Therefore, there arises no need to form the back gate with fine pattern, so that the manufacturing process of the semiconductor device can be simplified in comparison with the case of Japanese Patent Laid-open Official Gazette No. Sho. 62-277747.

According to still another aspect of the present invention, there is provided a method of manufacturing a semiconductor device comprising the steps of: forming a first conduction type well by introducing a first conduction type impurities into a partial region of the first conduction type semiconductor substrate, where an inside of an outline of the first conduction type well being integral planar shape; forming a second conduction type well, which has an integral planar shape obtained by inverting a planar shape of the first conduction type well, by introducing a second conduction type impurities into the semiconductor substrate; forming first and second gate electrodes on the first and second conduction type wells respectively with a gate insulating film interposed therebetween; forming a second conduction type source/drain region in the first conduction type well beside the first gate electrode; forming a first conduction type impurity diffusion region for well contact formed at a distance from the second conduction type source/drain region in a portion of the first conduction type well; forming a first conduction type source/drain region in the second conduction type well beside the second gate electrode; and forming an second conduction type impurity diffusion region for well contact in a portion of the second conduction type well which is located at a distance from the first conduction type source/drain region.

According to yet another aspect of the present invention, there is provided a method of manufacturing a semiconductor device comprising the steps of: forming a second conduction type well having a integral planar shape by introducing second conduction type impurities into a partial region of a silicon-on-insulator (SOI) substrate made by sequentially laminating a first conduction type support base, an embedded insulating film, and a silicon layer; forming a first gate electrode, on a region of the silicon layer where the second conduction type well is not formed, with an gate insulating film interposed therebetween, and forming a second gate electrode on the silicon layer over the second conduction type well with an gate insulating film interposed therebetween; forming a second conduction type source/drain region in the silicon layer beside the first gate electrode; forming a second conduction type impurity diffusion region for well contact in the second conduction type well; forming a first conduction type source/drain region in the silicon layer beside the second gate electrode; and forming a first conduction type impurity diffusion region for well contact in a portion of the support base which is located at a distance from the second conduction type well.

### BRIEF DESCRIPTION OF THE DRAWINGS

FIG. 1 is a graph for explaining a well-proximity effect.

FIGS. 2A to 2M are cross-sectional views of a semiconductor device according to a first embodiment of the present invention in the process of being manufactured.

FIGS. 3A to 3E are plan views of the semiconductor device according to a first embodiment of the present invention in the process of being manufactured.

FIG. 4 is a diagram of a configuration of a well designing system to be used in the case of each of the embodiments of the present invention.

FIG. 5 is a flowchart showing a well designing method using the designing system of FIG. 4.

FIGS. 6A and 6B are diagrams schematically showing contents to be processed in accordance with the flowchart shown in FIG. 5.

FIGS. 7A to 7C are cross-sectional views of a semiconductor device according to a third embodiment of the present invention in the process of being manufactured.

FIGS. 8A and 8B are plan views of the semiconductor device according to a third embodiment of the present invention in the process of being manufactured.

FIGS. 9A to 9H are cross-sectional views of a semiconductor device according to a fourth embodiment of the present invention in the process of being manufactured.

FIGS. 10A and 10B are plan views of the semiconductor device according to the fourth embodiment of the present invention in the process of being manufactured.

FIG. 11 is a cross-sectional view of another semiconductor device according to the fourth embodiment of the present invention.

FIG. 12 is a plan view showing a case where a p-well 20 has a planar shape with a hole made.

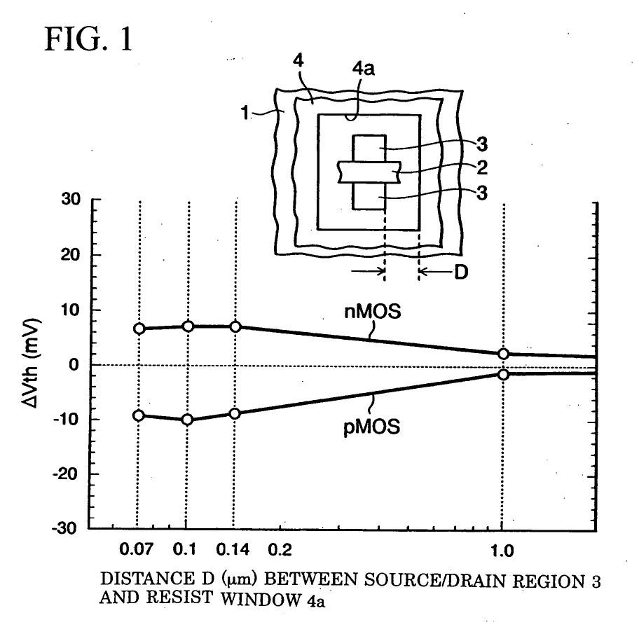

### DESCRIPTION OF THE PREFERRED EMBODIMENT

Detailed descriptions will be provided below for embodiments of the present invention with reference to the attached drawings.

(1) First Embodiment

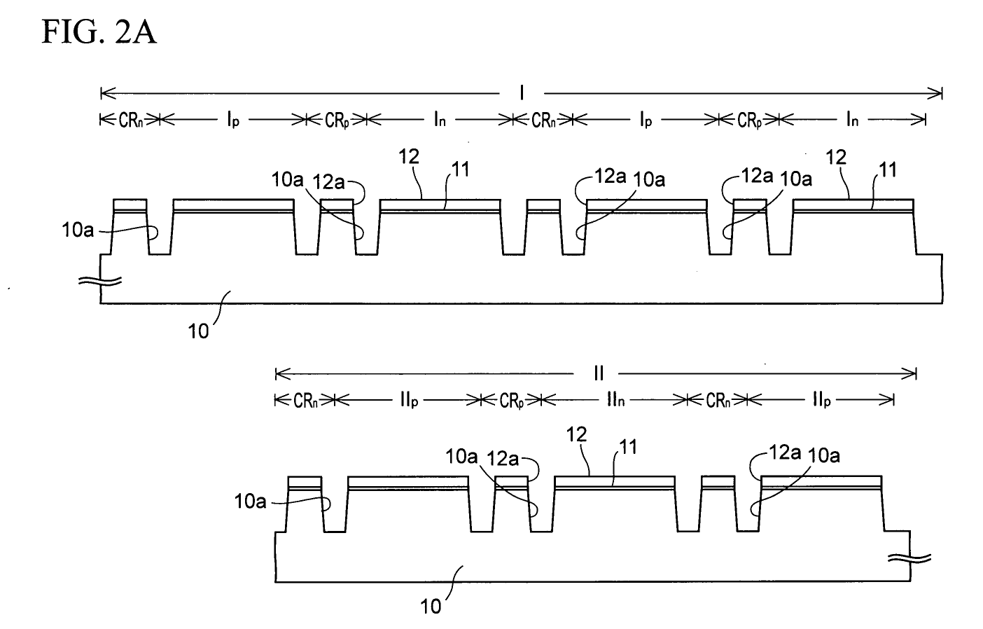

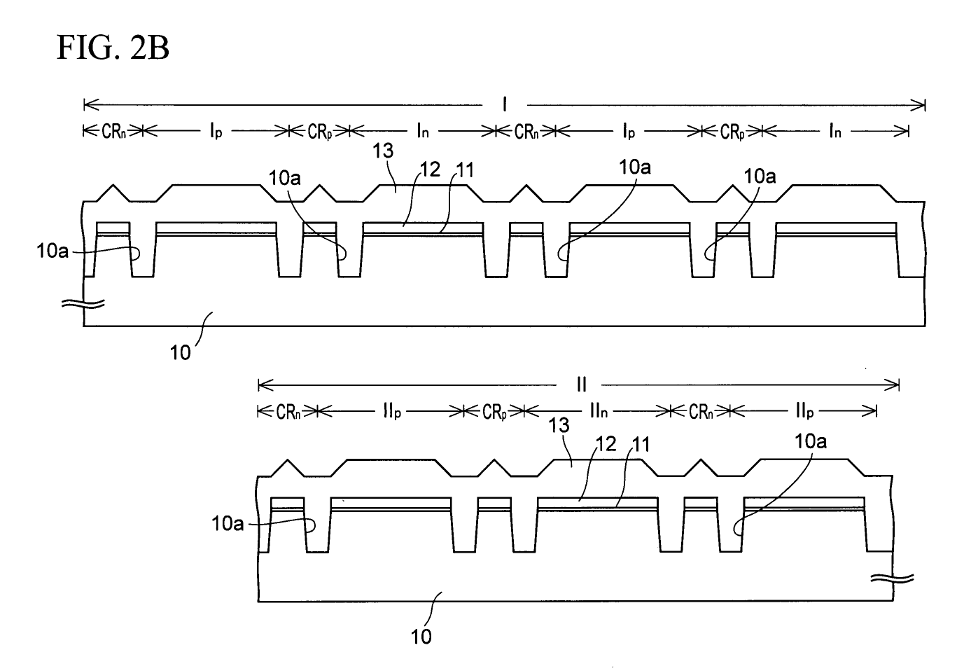

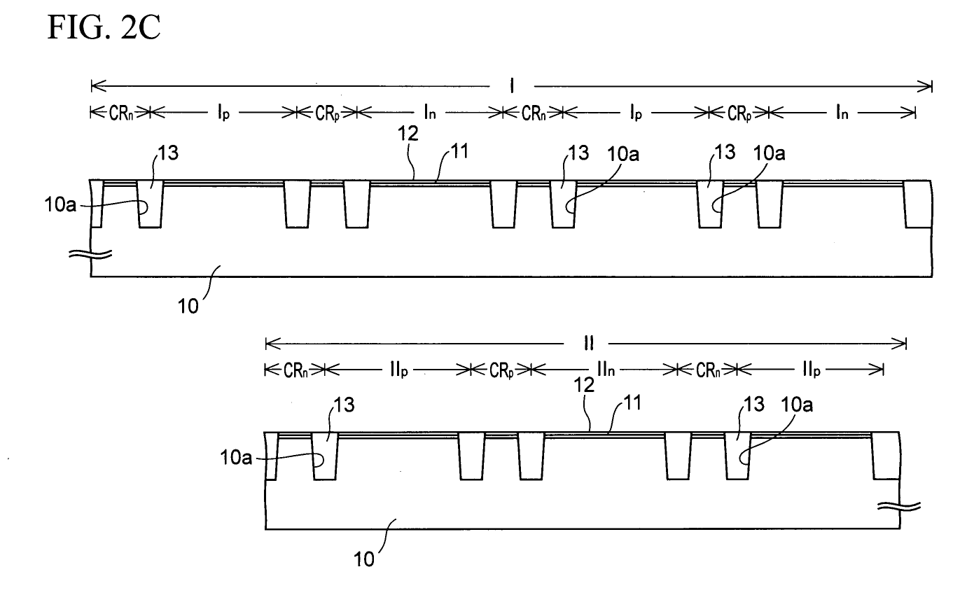

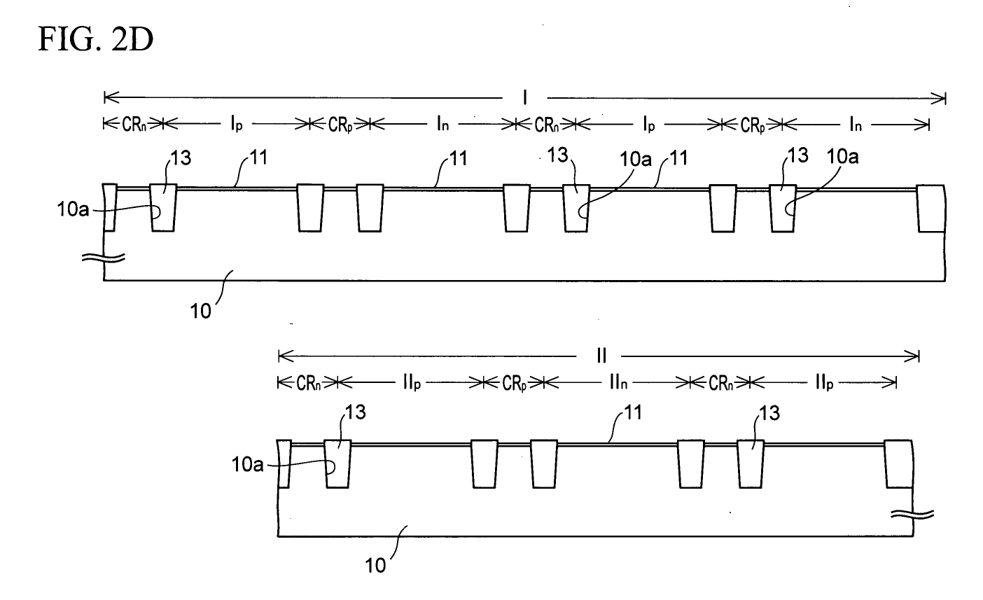

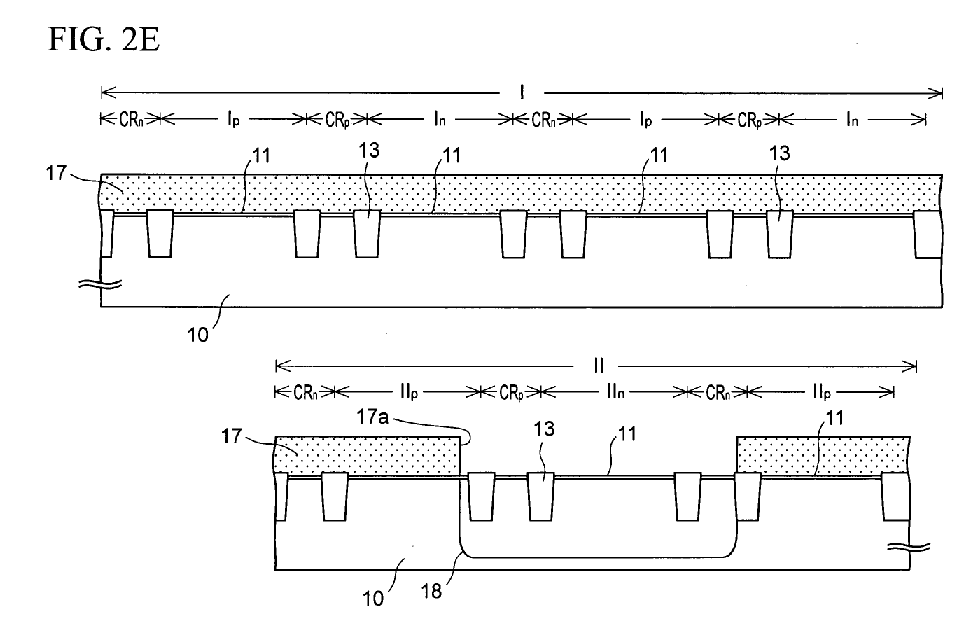

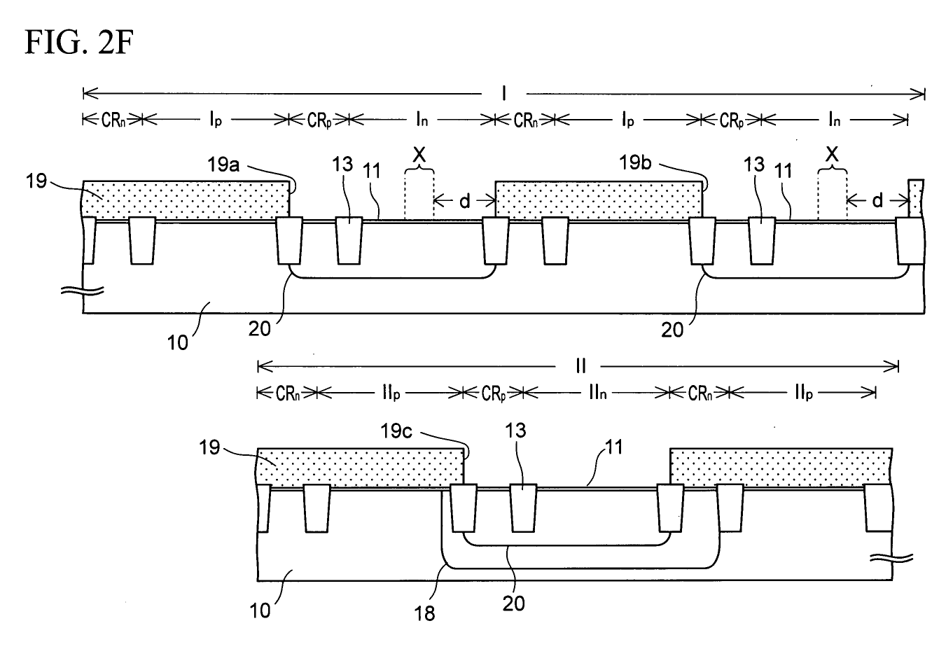

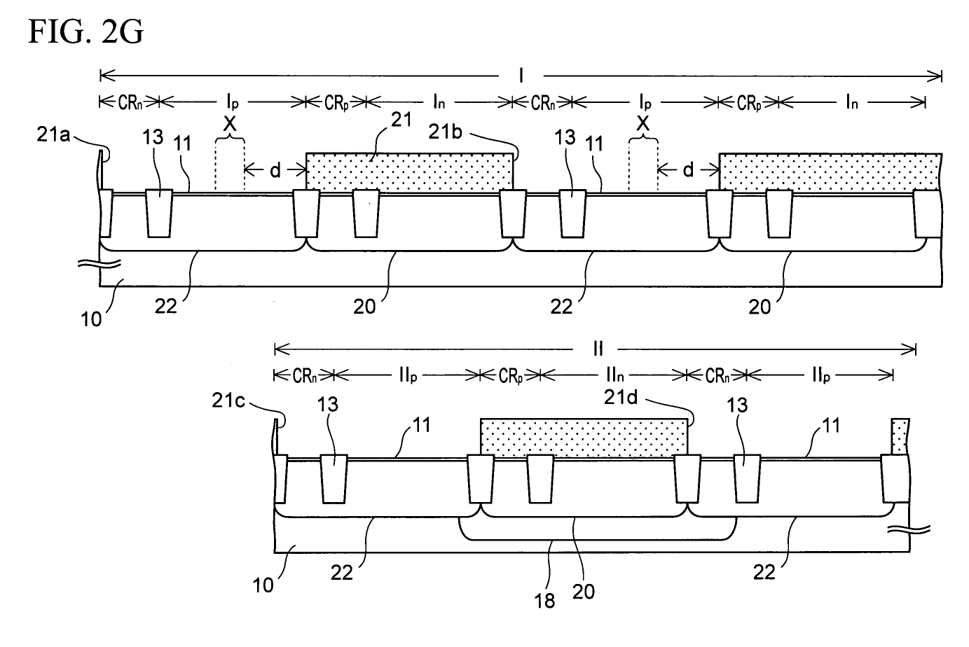

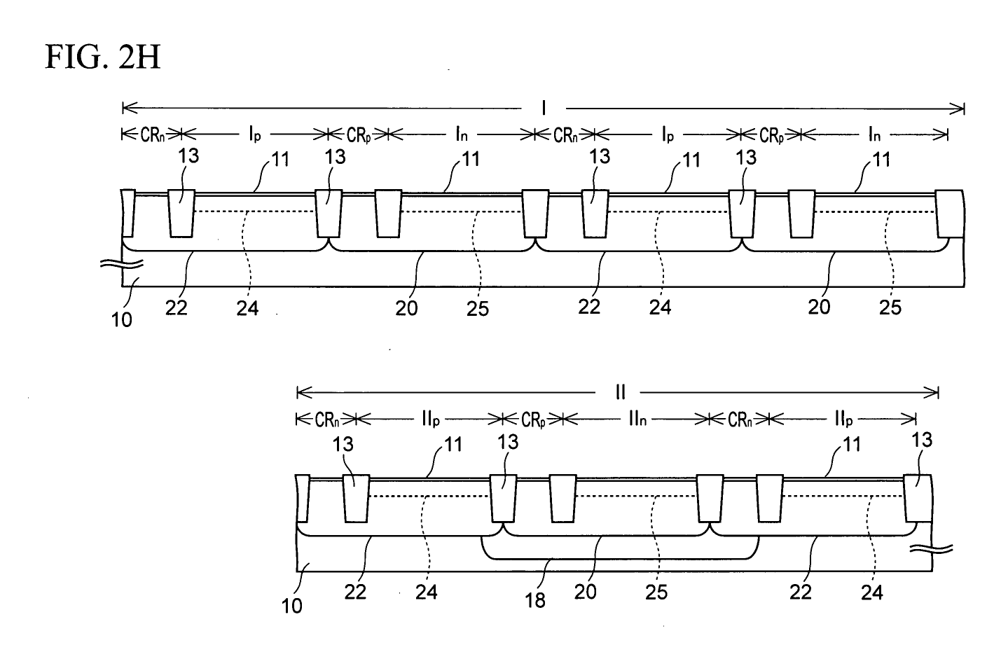

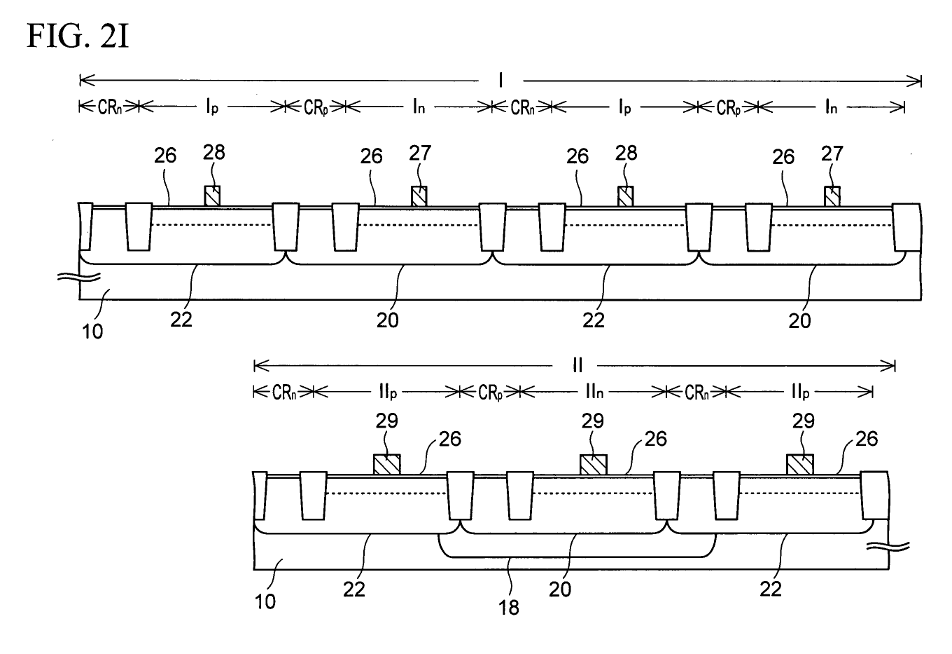

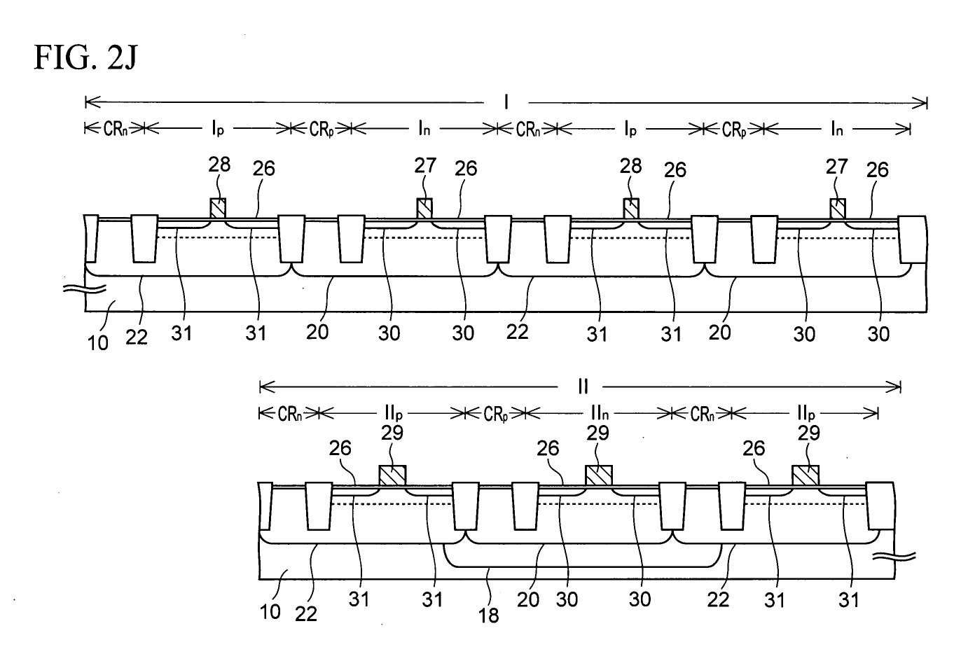

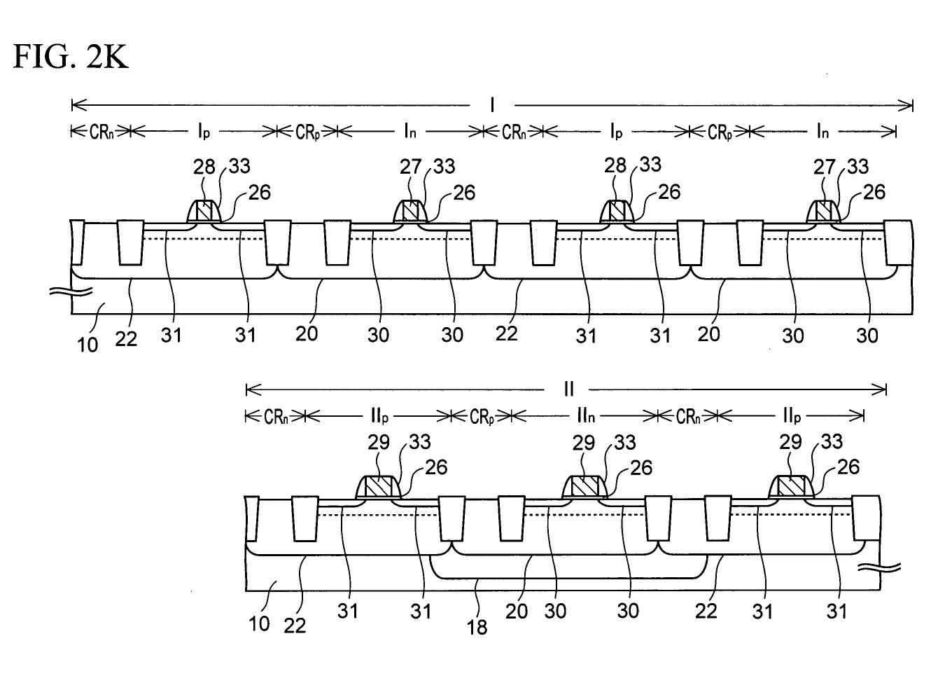

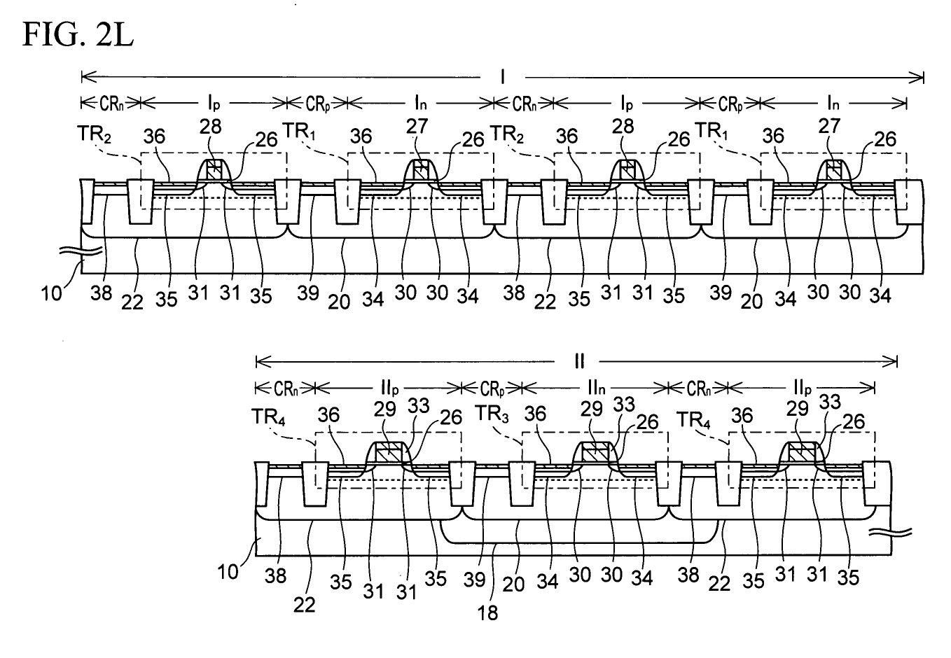

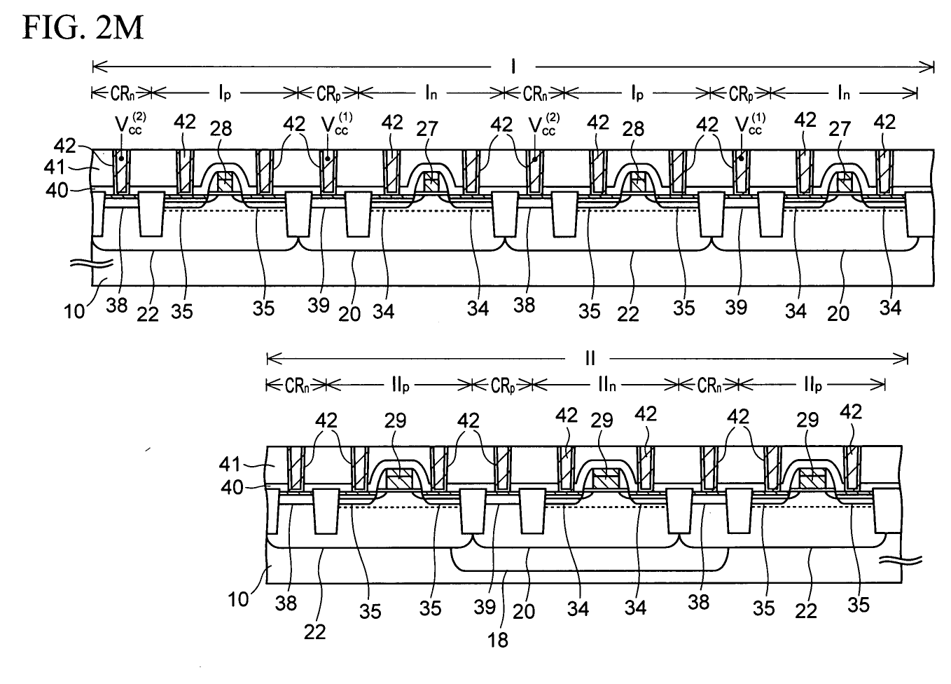

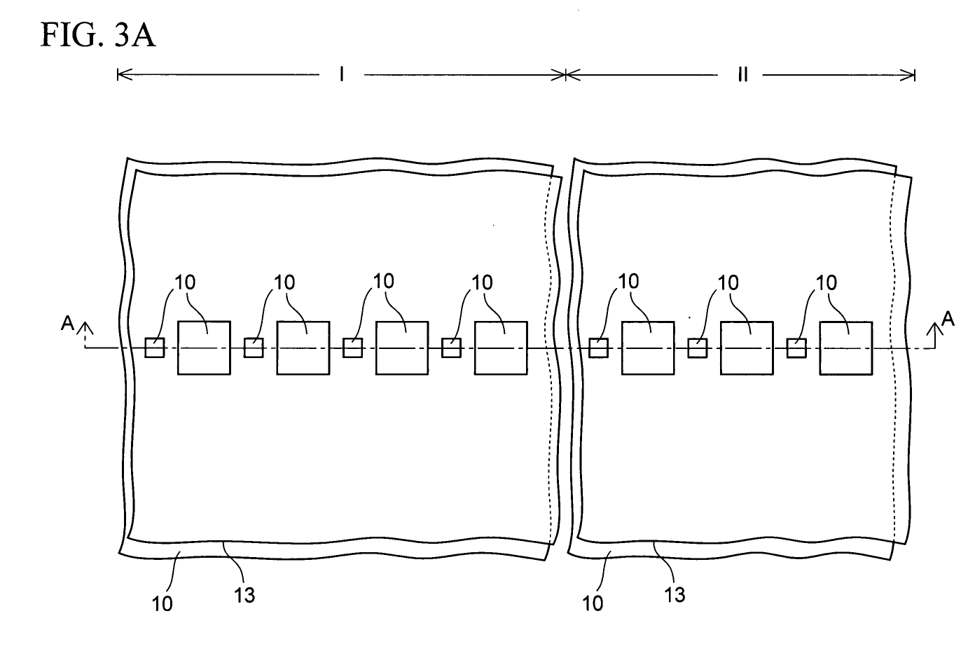

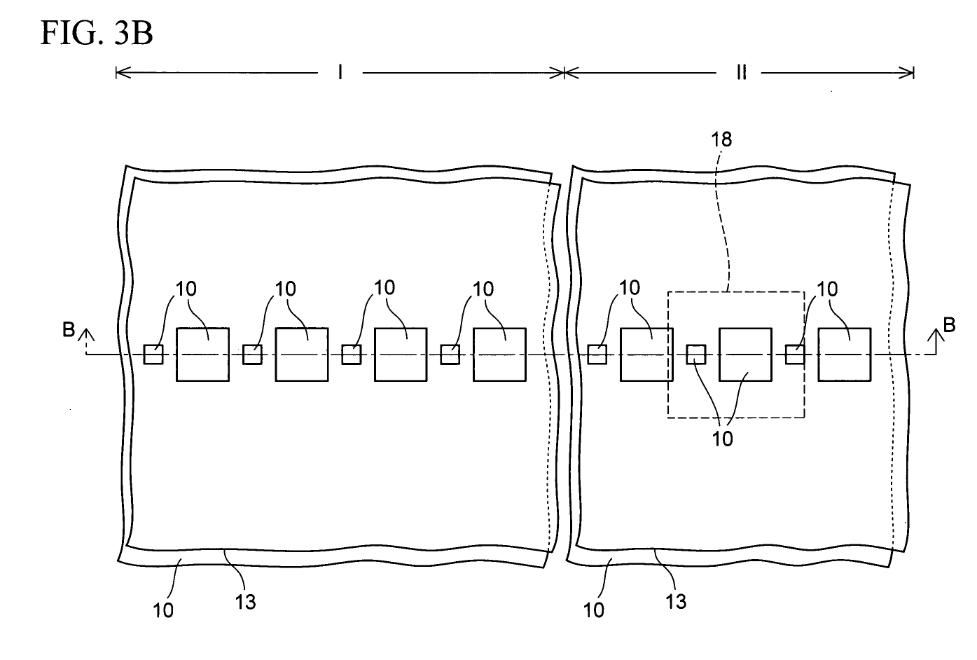

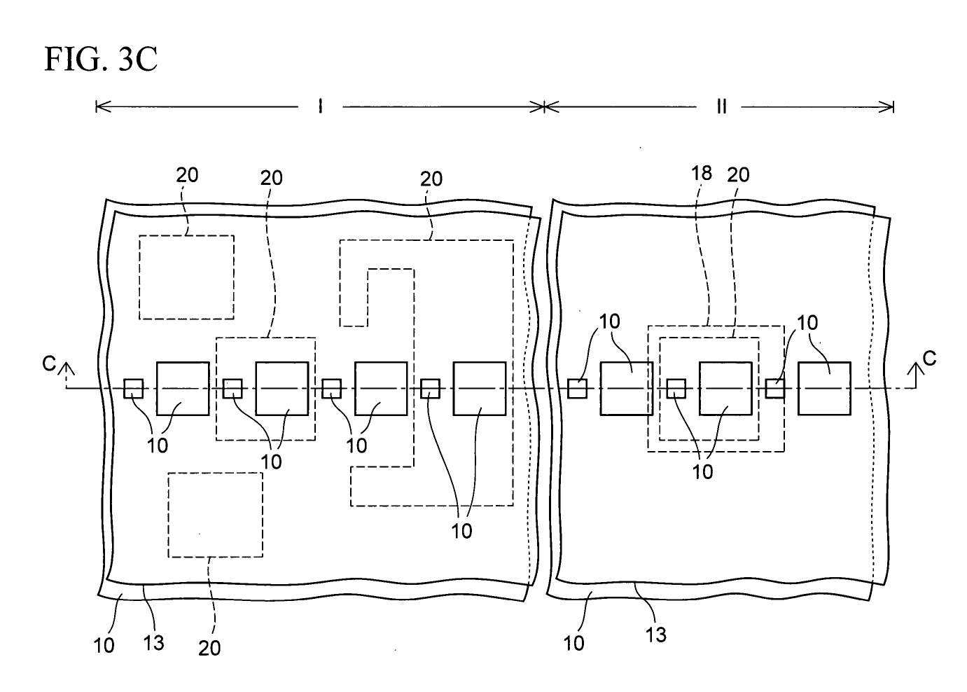

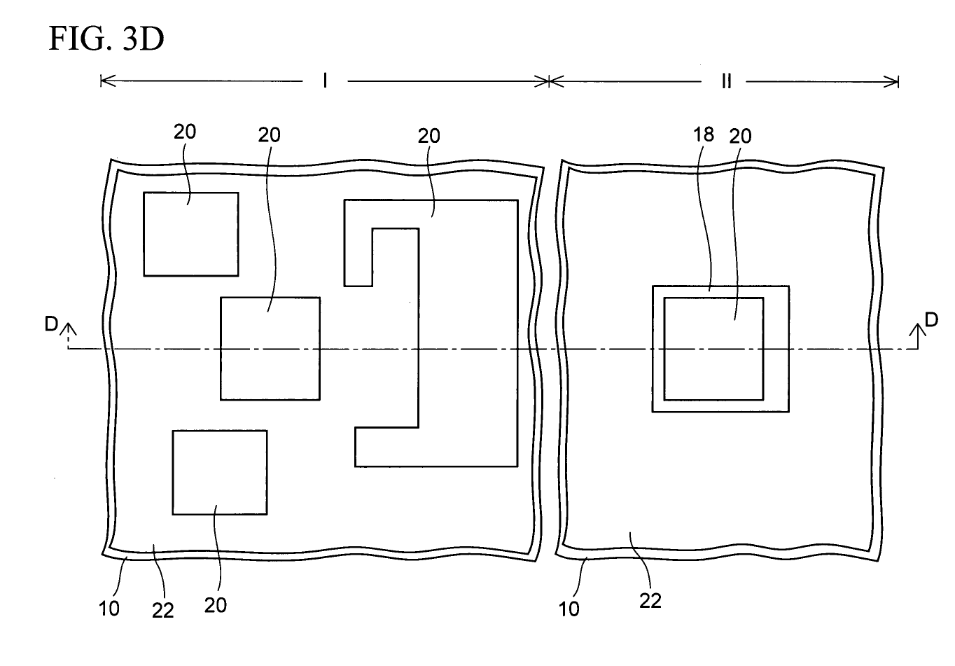

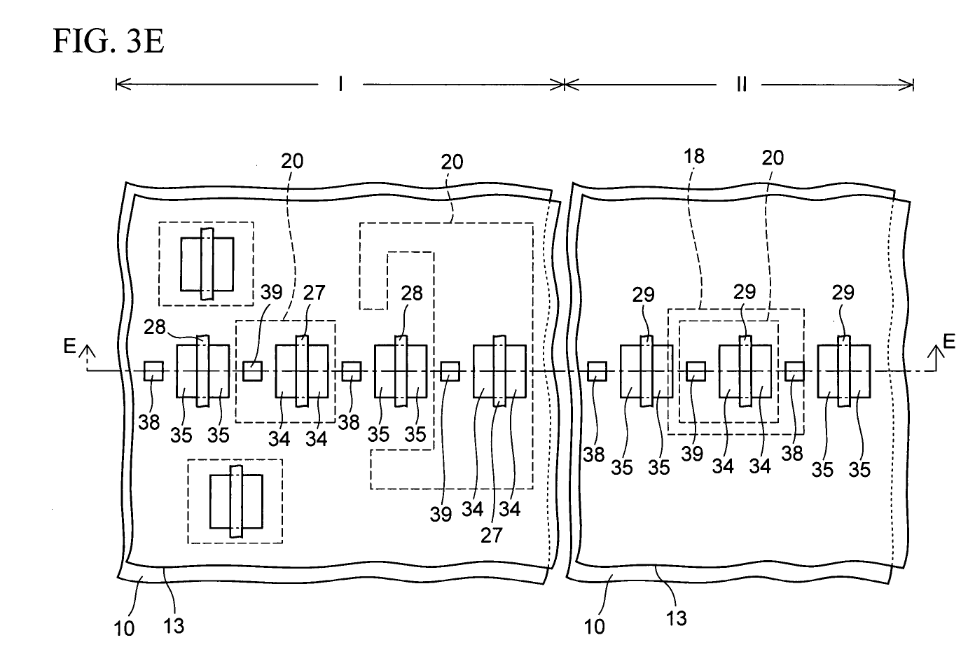

FIGS. 2A to 2M are cross-sectional views of a semiconductor device according to a first embodiment of the present invention in the process of being manufactured. FIGS. 3A to 3E are plan views of the semiconductor device in the process of being manufactured.

First of all, descriptions will be made for steps which are performed until a cross-sectional structure as shown in FIG. 2A is obtained.

Firstly, a thermal oxide film 11 is formed to a thickness of approximately 5 nm on a silicon substrate 10 having a digital circuit region I and an analog circuit region II. Thereafter, a silicon nitride (Si₃N₄) film 12 is formed to a thickness of approximately 100 nm on the thermal oxide film 11 by means of the reduced-pressure CVD method.

It should be noted that no specific restrictions are imposed on design rules respectively for the regions I and II. However, it is preferable that a transistor be miniaturized by means of applying, to the digital circuit region I, a rule specifying that components are fabricated as minute as possible, for example, a design rule specifying that a gate length is 90 nm.

On the other hand, it is preferable that a gate length be larger by means of applying, to the analog circuit region II, a design rule less detailed than that applied to the digital circuit region I so that the transistor is as least susceptible to influence of a well-proximity effect as possible.

Incidentally, descriptions will be provided below for the case where an analog circuit region is embedded with a digital circuit region on the same silicon substrate 10. However, the analog circuit region is not essential for the present invention, and it does not matter that the analog circuit region is omitted. In this case, the analog circuit region II does not have to be defined in the silicon substrate 10.

Furthermore, no specific restrictions are imposed on a conduction type of the silicon substrate 10. It is preferable, however, that a p-type (first conduction type) silicon wafer be used as the silicon substrate 10. This is because a p-type silicon wafer is less defective than an n-type silicon wafer due to excellent gettering properties.

After the films 11 and 12 are formed in the aforementioned manner, the films 11 and 12 are etched by means of the reactive ion etching (RIE) method using a fluorine-contained gas as the etching gas while using a resist pattern (not shown) as the etching mask. Thus, the opening (not shown) is formed in these films 11 and 12.

After the resist pattern is removed, by use of the RIE method using a chlorine-contained gas as the etching gas, the silicon substrate 10 is etched through the opening. Thereby, element-isolation trenches 10a each with a depth of approximately 400 nm are formed.

Then, a silicon oxide film to serve as an element-isolation insulating film 13 is formed on the silicon nitride film 12 by means of the high density plasma CVD (HDPCVD) method using silane as the reaction gas, as shown in FIG. 2B. Thus, the element-isolation trenches 10a are completely buried with the silicon oxide film. Incidentally, before this element-isolation insulating film 13 is formed, the inner surfaces respectively of the element-isolation trenches 10a may be slightly thermally oxidized for the purpose of recovering the inner surfaces from damage which the inner surfaces suffered while the element-isolation trenches 10a were formed by etching.

Subsequently, as shown FIG. 2C, excessive element-isolation insulating film 13 on the silicon nitride film 12 are polished and removed by means of the chemical mechanical polishing (CMP) method. Thus, the element-isolation insulating film 13 is left only in the element-isolation insulating trenches 10a. Such an element-isolation structure is called as shallow trench isolation (STI). Incidentally, the excessive element-isolation insulating film 13 may be removed by means of the etch-back method using the RIE method, instead of the CMP method. Furthermore, instead of the STI, local oxidation of silicon (LOCOS) may be adopted as the element-isolation structure.

Thereafter, the element-isolation insulating film 13 are annealed for approximately 30 seconds with the substrate temperature of approximately 1000° C. Thus, the film density of the element-isolation insulating film 13 is increased. The annealing may precede the polish using the CMP method.

The steps performed up to this, the n-type MOS transistor forming regions Iₙ, and IIₙ, the p-type MOS transistor forming regions Iₚ and IIₚ, the n-type contact regions CRₙ, as well as the p-type contact regions CRₚ are defined on the silicon substrate 10 by the element-isolation insulating film 13.

FIG. 3A is a plan view of the semiconductor device which is obtained by the completion of the steps. Aforementioned FIG. 2B corresponds to a cross-sectional view of the semiconductor device taken along the line A-A of FIG. 3A. Incidentally, the thermal oxide film 11 and the silicon nitride film 12 are omitted from FIG. 3A for the purpose of preventing the figure from becoming complicated.

As shown in FIG. 3A, the element-isolation insulating film 13 has openings in its portions corresponding to the MOS transistor forming regions Iₙ, lₚ, IIₙ, and IIₚ as well as the contact regions CRₙ, and CRₚ.

Then, as shown in FIG. 2D, the wet etching of the silicon nitride film 12 is carried out by use of phosphoric acid. Thus, the silicon nitride film 12 is removed, and the thermal oxide film 11 underneath the silicon nitride film 12 is exposed.

Next, descriptions will be made for steps which are performed until a cross-sectional structure as shown in FIG. 2E is obtained.

First, a photoresist is applied to the entire upper surface of the resultant silicon substrate 10, and the photoresist is exposed and developed. Thereby, a first resist pattern 17, which has a resist window 17a in the analog circuit region II, is formed.

Subsequently, As⁺ ions are ion-implanted into the silicon substrate 10 through the resist window 17a. Thereby, a deep n-well 18 is formed in the n-type MOS transistor forming region IIₙ and its peripheral region. Thereafter, the first resist pattern 17 is removed.

FIG. 3B is a plan view of the semiconductor device which is obtained by the completion of these steps. Aforementioned FIG. 2E corresponds to a cross-sectional view of the semiconductor device taken along the line B-B of FIG. 3B. Incidentally, the thermal oxide film 11 is omitted from FIG. 3B for the purpose of preventing the figure from becoming complicated.

Subsequently, as shown in FIG. 2F, a second resist pattern 19 with resist windows 19a to 19c is formed on the entire upper surface of the silicon substrate 10. In the digital circuit forming region I, the n-type MOS transistor forming region Iₙ , and the p-type contact region CRₚ adjacent to the region Iₙ are exposed though each of the resist windows 19a and 19b. Furthermore, in the analog circuit forming region II, the n-type MOS transistor forming region IIₙ and the p-type contact region CRₚ adjacent to the region IIₙ are exposed though the resist windows 19c.

Then, B⁺ ions (boron ions) are ion-implanted into the silicon substrate 10 through the resist windows 19a to 19c. As a result of the ion implantation, in the digital circuit region I, p-wells (first conduction type wells) 20 are formed in the n-type MOS transistor forming region Iₙ and the adjacent p-type contact region CRₚ of the silicon substrate 10. On the other hand, in the analog circuit region II, a p-well 20 is formed in the silicon substrate 10 of the n-type MOS transistor forming region IIₙ, and the adjacent p-type contact region CRₚ so as to be included in the deep n-well 18

It should be noted that no specific restrictions are imposed on conditions for the ion implantation. In the case of this embodiment, however, the acceleration energy is 150 keV, and the dose is 3×10¹³ cm⁻².

Here, p-wells 20 are to be formed in the surface layer of the silicon substrate 10 and do not have to be formed in the deep portion of the silicon substrate 10. Therefore, the acceleration energy of the ion implantation for the p-wells 20 can be as small as approximately 150 keV. Consequently, even if ions collide against the side surfaces of the resist windows 19a and 19b, most of the kinetic energy of the ions is absorbed by the side walls. Accordingly, almost none of the ions are so reflected at the side surface to reach channel regions X in the respective MOS transistors. As a result, the well-proximity effect does not conspicuously occur.

It should be noted that for the purpose of sufficiently suppressing the well-proximity effect, it is preferable that the resist openings 19a and 19b be separated from the channel region X by the sufficiently large distance d, to reduce the number of the ions unnecessarily introduced into the channel region X by the reflection at the side surfaces of the resist openings 19a and 19b. For example, the required distance d is equal to or more than 0.4 μm in the case where the gate length is 90 nm.

Thereafter, the second resist pattern 19 is removed.

FIG. 3C is a cross-sectional view of the semiconductor device obtained by the completion of these steps. Aforementioned FIG. 2F corresponds to a cross-sectional view of the semiconductor device taken along the line C-C of FIG. 3C. Incidentally, the thermal oxide film 11 is omitted from FIG. 3C for the purpose of preventing the figure from becoming complicated.

As shown in FIG. 3C, a plurality of p-wells 20 are formed in the silicon substrate 10. However, no hole is made in any of p-well 20. As such, the inside surrounded by the outline of each of the p-wells 20 is integrated, and there exists no p-wells 20 having a planar shape with hole like a ring.

Next, descriptions will be made for steps which are performed until a cross-sectional structure as shown FIG. 2G is obtained.

First, a photoresist is applied to the entire upper surface of the silicon substrate 10, and the photoresist is exposed and developed. Thereby, a third resist pattern 21 is formed.

No specific restrictions are imposed on the planar layout of the third resist pattern 21 as long as it has resist windows 21a to 21d on p-type MOS transistor forming regions Iₚ, IIₚ and adjacent n-type contact region CRₙ as shown in the figure.

In the case of the present embodiment, however, an inverse pattern of the second resist pattern 19, which has been described with reference to FIG. 2F, is used as the planar layout of the third resist pattern 21 for the purpose of reducing burden on a semiconductor device designer. According to such layout, the exposed portions of the silicon substrate 10 which have not been covered with the second resist pattern 19 are covered with the third resist pattern 21. On the contrary, the portions of the silicon substrate 10, which have been covered with the second resist pattern 19, are not covered with the third resist pattern 21 and are exposed.

Subsequently, n-type impurities, for example, P⁺ ions, are ion-implanted into the silicon substrate 10 through these resist windows 21a to 21d. Thereby, n-wells (second conduction type wells) 22 are formed in the each region described above. Although the condition on this ion implantation is not limited, the acceleration energy is set to 300 keV, and the dose is set to 3×10¹³ cm⁻² in the present embodiment.

Since the inverse pattern of the second resist pattern 19 is used as the third resist pattern 21 as described above, the planar shapes of the n-wells 22 are equal to those which are obtained by inverting the p-wells 20.

As in the case of the p-wells 20 which have been described with reference to FIG. 2F, for the purpose of sufficiently suppressing the well-proximity effect due to the ion implantation, it is preferable that the side surfaces of the resist windows 21a and 21b be kept away from the channel regions X by a sufficient distance d, for example, equal to or larger than 0.4 μm.

Thereafter, the third resist pattern 21 is removed.

Up to these steps, a basic well structure of the semiconductor device according to the present embodiment has been completed.

By caring out the above ion implantation, the p-well 20 is surrounded by the n-well 22 and the deep n-well 18, and thus the p-well 20 is electrically isolated from the surroundings by the p-n junction.

FIG. 3D is a plan view of the semiconductor device which is obtained by the completion of these steps. Aforementioned FIG. 2G is a cross-sectional view of the semiconductor device taken along the line D-D of FIG. 3D. Incidentally, the thermal oxide film 11 and the element-isolation insulating film 13 are omitted from FIG. 3D for the purpose of making the plan layout of the wells easy to see.

As described above, in the digital circuit region I, each of the p-wells 20 is formed to have a planar shape with no hole. Therefore, even if an inverse pattern of this p-well 20 is used as a pattern of the n-well 22 in the aforementioned manner, the n-well 22 is not surrounded by the p-wells 20 and is not electrically isolated. As a result, the n-well 22 is integrally formed in the digital circuit region I of the resultant silicon substrate 10, and accordingly is not separated by the p-wells 20. Consequently, unlike the case where the n-well 22 is separated into a plurality of portions, a deep n-well for electrically connecting a plurality of portions of the n-well 22 need not be formed in the digital circuit region I.

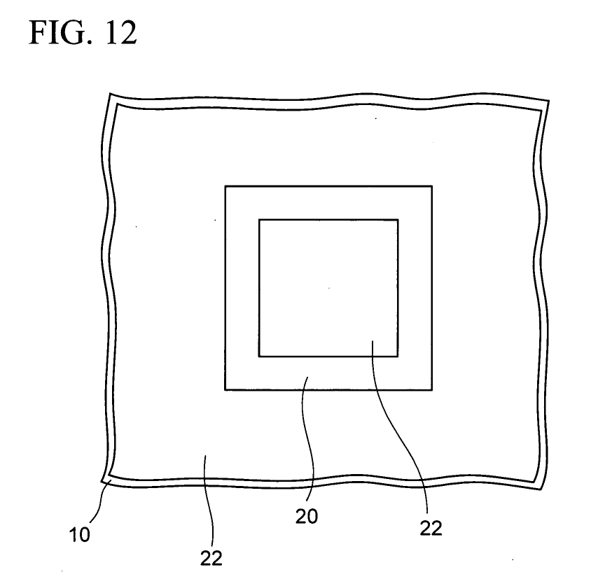

FIG. 12 is a plan view showing the case where, unlike the case of the present embodiment, a p-well 20 has a (ring like) planar shape with a hole.

In such a case, a part of the n-well 22 inside the ring like p-well 20 and the other part of the n-well 22 outside the p-well 20 are electrically separated from each other by the interface between the p-well 20 and each of the parts of the n-well 22 as well as the p-n junction between the p-type silicon substrate 10 and each of the parts of the n-well 22. For this reason, in this case, a deep n-well is needed for electrically connecting the separated parts of the n-well 22 with each other. If, however, the deep n-well is thus formed, a threshold voltage of the transistor changes due to the well-proximity effect, as described above.

Subsequently, as shown in FIG. 2H, B⁺ ions to serve as p-type impurities are selectively ion-implanted into the n-type MOS transistor forming regions Iₙ, and IIₙ. Thus, p-type diffusion regions 25 for adjusting the respective threshold voltages of the n-type MOS transistors are formed in the n-type MOS transistor forming regions Iₙ and IIₙ Thereafter, As⁺ ions to serve as n-type impurities are selectively implanted in the p-type MOS transistor forming regions Iₚ and IIₚ. Thus, n-type diffusion regions 24 for adjusting the respective threshold voltages of the p-type MOS transistors are formed in the p-type MOS transistor forming regions Iₚ and IIₚ.

Incidentally, the implantation of the p-type impurities and the implantation of the n-type impurities are separately performed by use of the respective resist patterns (not shown).

Thereafter, an activation annealing for the diffusion regions is performed under the substrate temperature of 1000° C. and the process time of 10 seconds. Thereby, the impurities in each of the p-wells 20 and the n-wells 22 are activated.

Next, descriptions will be made for steps which are performed until a cross-sectional structure as shown in FIG. 2I is obtained.

First, the thermal oxide film 11, which are damaged by the ion implantation for forming the p-wells 20 and the n-wells 22, is removed by the wet etching using a hydrofluoric solution. Thus, the cleansed surface of the silicon substrate 10 is exposed. Then, the surface of the silicon substrate 10 is thermally oxidized once again to form a thermal oxide film to the thicknesses of about 1 nm, and this thermal oxide film is used as a gate insulating film 26.

Subsequently, a polycrystalline silicon film is formed to a thickness of approximately 100 nm on the gate insulating film 26 by means of the thermal CVD method using silane as the reaction gas. Thereafter, this polycrystalline silicon film is patterned. Thereby, first and second gate electrodes 27 and 28 are formed on the wells 20 and 22 respectively in the digital circuit forming region, and a third gate electrode 29 is formed in the analog circuit forming region II.

It should be noted that no specific restrictions are imposed on the gate lengths of the first to third gate electrodes 27 to 29. However, it is preferable that, as described above, the gate length of the third gate electrode 29 in the analog circuit II be set longer than those of the first and second gate electrodes 27 and 28 in the digital circuit region I.

By making the gate length of the third gate electrode 29 longer, change in the threshold voltage of the n-type MOS transistor formed in the region IIₙ can be made smaller, even if the n-type impurities are unnecessarily implanted into the n-type MOS transistor forming region IIₙ due to the well-proximity effect while the deep n-well 18 is being formed.

Then, as shown in FIG. 2J, As⁺ions to serve as n-type impurities are ion-implanted into the silicon substrate 10 in the n-type MOS transistor forming regions Iₙ and IIₙ with the following conditions: the acceleration energy of 5 keV and the dose of 5×10¹⁴ cm⁻². Thus, n-type source/drain extensions 30 are formed beside the gate electrodes 27 in the regions Iₙ and beside the gate electrode 29 in the region IIₙ.

Subsequently, BF₂⁺ ions to serve as p-type impurities are implanted into the silicon substrate 10 in the p-type MOS transistor forming regions Iₚ and IIₚ. Thus, p-type source/drain extensions 31 are formed beside the gate electrodes 28 in the regions Iₚ and beside the gate electrodes 29 in the region IIₚ. No specific restrictions are imposed on this ion implantation. In the present embodiment, however, the acceleration energy is 5 keV, and the dose is 5×10¹⁴ cm⁻².

Incidentally, the implantation of the p-type impurities and the implantation of the n-type impurities are separately performed by use of the respective resist patterns (not shown). After the ion implantations are completed, the resist patterns are removed.

Then, as shown in FIG. 2K, after an insulating film is formed on the entire upper surface of the silicon substrate 10, the insulating film is etch-backed, and the insulating film is left beside the gate electrodes 27 to 29 as insulating side walls 33. In the present embodiment, a silicon oxide film with a thickness of approximately 100 nm formed by the thermal CVD method is employed as the insulating film. Incidentally, through performing the etch-back method, portions of the gate insulating film 26 which are not covered with the gate electrodes 27 to 29 or with the insulating side walls 33 are also etched and removed.

Next, descriptions will be made for steps which are performed until a cross-sectional structure as shown in FIG. 2L is obtained.

First, P⁺ ions to serve as n-type impurities are ion-implanted into the silicon substrate 10 in the n-type MOS transistor forming region Iₙ and IIₙ as well as the n-type contact regions CRₙ with the following conditions: the acceleration energy of 20 keV and the dose of 1×10¹⁵ cm⁻². Thus, n-type source/drain regions 34 are formed beside the gate electrodes 27 and 28 in the region Iₙ, and IIₙ, and n-type impurity diffusion regions 38 for well contact are formed in each of the contact regions CRₙ.

Next, p-type impurities, B⁺ ions for example, are ion-implanted into the silicon substrate 10 in the p-type MOS transistor forming regions Iₚ and IIₚ as well as the p-type contact regions CRₚ. Thus, p-type source/drain regions 35 are formed beside the gate electrodes 28 and 29 in the regions Iₚ and IIₚ, and p-type impurity diffusion regions 39 for well contact are formed in each of the contact regions CRₚ.

Incidentally, the implantation of the n-type impurities and the implantation of the p-type impurities are separately performed by use of the respective resist pattern (not shown).

After the resist patterns are removed, the activation annealing is performed at the substrate temperature of 1000° C. for a process time of one second. Thus, the impurities in each of the source/drain regions 34 and 35 as well as the impurities diffusion regions 38 and 39 are activated.

Subsequently, a refractory metal layer such as a cobalt layer is formed on the entire upper surface of the silicon substrate 10 by means of the spattering method. Thereafter, the refractory metal layer is annealed. Thus, the refractory metal layer and the silicon are reacted with each other, so that a refractory-metal silicide layer 36 is formed on each of the source/drain regions 34 and 35. The refractory-metal silicide layer 36 is formed on each of the gate electrodes 27 to 29, and the electric resistance of these gate electrodes 27 to 29 is made lowered.

After that, unreacted refractory metal layer left on the element-isolation insulating film 13 and the like is removed by wet-etching.

Up to this step, n-type MOS transistors TR₁ and p-type MOS transistors TR₂ are formed in the silicon substrate 10 of the digital circuit region I, and an n-type MOS transistor TR₃ and p-type MOS transistors TR₄ are formed in the silicon substrate 10 of the analog circuit region II.

FIG. 3E is a plan view of the semiconductor device which is obtained by the completion of these steps. Aforementioned FIG. 2L corresponds to a cross-sectional view of the semiconductor device taken along the line E-E of FIG. 3E. Incidentally, the refractory-metal silicide layer 36, the insulating side walls 33, the source/drain extensions 30 and 31 are omitted from FIG. 3E for the purpose of making the figure easy to see.

Next, descriptions will be made for steps which are performed until a cross-sectional structure as shown in FIG. 2M is obtained.

First, a silicon nitride film is formed to a thickness of approximately 50 nm on the entire upper surface of the silicon substrate 10 by means of the plasma CVD method. The silicon nitride film is used as a cover insulating film 40. In addition, a silicon oxide film to serve as an interlayer dielectric 41 is formed to a thickness of approximately 700 nm on the cover insulating film 40 by means of the HDPCVD method. Thereafter, the upper surface of the interlayer dielectric 41 is polished and planarized by means of the CMP method.

Subsequently, each of the cover insulating film 40 and the interlayer dielectric 41 is patterned. Thus, contact holes are formed in the cover insulating film 40 and the interlayer dielectric 41. Thereafter, a titanium film and a titanium nitride film to serve as a glue film are formed in this order, on the inner surfaces of these contact holes and on the upper surface of the interlayer dielectric 41 by means of the spattering method. In addition, a tungsten film is formed on this glue film by means of the CVD method. Thus, the contact holes are fully buried with this tungsten film. Then, excessive portions of the tungsten film and the glue film on the interlayer dielectric 41 are polished and removed by means of the CMP method. The glue film and the tungsten film are left only in the contact hole as conductive plugs 42.

The basic structure of the semiconductor device according to the present embodiment has been completed through the aforementioned steps.

According to this semiconductor device, as shown in FIG. 2M, the p-type impurity diffusion regions 39 for well contact and the conductive plugs 42 formed thereon are electrically connected with each other in the digital circuit region I. A first substrate bias voltage Vcc⁽¹⁾ is applied to each of the p-wells 20 in the digital circuit region I through the corresponding conductive plug 42.

Similarly, a second substrate bias voltage Vcc⁽²⁾ is applied to the n-well 22 in the digital circuit region I through the n-type impurity diffusion region 38 for well contact and the conductive plug 42 formed thereon.

Even if the gate lengths of the gate electrodes 27 and 28 are varied due to the patterning error, the threshold voltages of the transistors TR₁ and TR₂ can be made closer to the designed voltage by applying the substrate bias voltages Vcc⁽¹⁾ and Vcc⁽²⁾ to the wells 20 and 22.

Furthermore, as shown in the FIG. 3D, the pattern of the n-well 22 and the pattern of the p-wells 20 are inverse to each other in the digital circuit region I, and each of the p-wells 20 is formed to have a planar shape with no hole. Therefore, the n-well 22 is not separated by the p-wells 20 so that the n-well 22 is formed integrally. Consequently, no deep n-well is needed in the digital circuit region I for electrically connecting the separated parts of the n-well, and the second substrate bias voltage Vcc⁽²⁾ can be evenly applied to the entire n-well 22 through the conductive plugs 42 shown in FIG. 2M.

FIG. 2M shows a plurality of conductive plugs 42 for applying the substrate bias voltage Vcc⁽²⁾ to the n-well 22. However, it should be noted that since the n-well 22 is formed integrally, the substrate bias voltage Vcc⁽²⁾ can be applied to the entire n-well 22 even if only a single conductive plug 42 connected to the n-well 22 is formed. It is also the case for a third and a fourth embodiments, which will be described later.

In addition, since there is no need to form the deep n-well in the digital circuit region I as described above, the threshold voltages of the MOS transistors TR₁ and TR₂ (see FIG. 2L) can be prevented from varying due to the well-proximity effect, and accordingly these transistors can be precluded from malfunctioning.

Moreover, in the case where the deep n-well is formed in the digital circuit region I, it is difficult to miniaturize the semiconductor device, since the side surfaces of the resist windows used for the ion implantation needs to be formed at a distance from the activation regions of the transistors larger for the purpose of reducing the well-proximity effect and thus the planar size of the deep n-well must be designed larger.

On the contrary, in the present embodiment, such a deep n-well need not be formed. This makes room in the layout for the semiconductor device by a planar size of the deep n-well. By using this room, it is made possible to perform miniaturization of the semiconductor device, including making widths of interconnects smaller. For example, in the case of a design rule specifying that the gate length is 90 nm, the maximum width of the deep n-well is typically approximately 1.2 μm, whereas the maximum width of the n-well 22 formed in this embodiment is approximately 0.62 μm. Therefore, it is made possible in the present embodiment to shorten the width of the interconnect smaller by half in comparison with the case where the deep n-well is formed.

Additionally, the n-well 22 is formed in a shallower portion of the silicon substrate 10 than the deep n-well, so that the acceleration energy in the ion-implantation for forming the n-well 22 can be made lower. In the ion implantation steps, it does not take so long time to implant a larger dose of ions with a lower acceleration energy and thus the throughput does not decrease to a large extent, although it takes vast time to implant a larger dose of ions with a higher acceleration energy.

Consequently, at the time of forming the n-well 22, a larger dose of ions can be implanted than for forming the deep n-well while suppressing the significant decrease in the throughput, so that the resistance of the n-well 22 can be sufficiently lowered. For example, a typical sheet resistance of the deep n-well is 1000 Ω/, whereas the sheet resistance of the n-well 22 is 560 Ω/ in the present embodiment, which is approximately half that of the deep n-well.

As a result, a voltage drop in the n-well 22 formed integrally in the digital circuit region I of the silicon substrate 10 can be reduced. This makes it possible to prevent the electric potential of the n-well 22 from varying from one position to another due to a voltage drop. Accordingly, it is made possible to prevent individual differences in property from occurring among the plurality of p-type MOS transistors TR₂.

Moreover, since it is not necessary to form the deep n-well in the digital circuit region 1, a step of forming the deep n-well can be eliminated. Accordingly, manufacturing cost for the semiconductor device can be lowered by the cost for forming the deep n-well.

(2) Second Embodiment

In the first embodiment, the p-well 20 is formed to have the planar shape with no hole, as described above with reference to FIG. 3D.

The p-well 20 is automatically designed by the design system such as the computer aided design (CAD). In the CAD system, a plurality of small rectangles constituting the outline of the p-well 20 are formed one after another, and these rectangles are connected to each other and made into the p-well 20.

However, if the p-well 20 is formed in accordance with a usual design flow which is different from the design flow of the present invention, it is likely that the plurality of small rectangles may be arranged continuously in the form of a ring, and that accordingly a hole is made in the p-wells 20.

In the present embodiment, descriptions will be made for a method of designing p-wells 20, which is able to avoid such a problem.

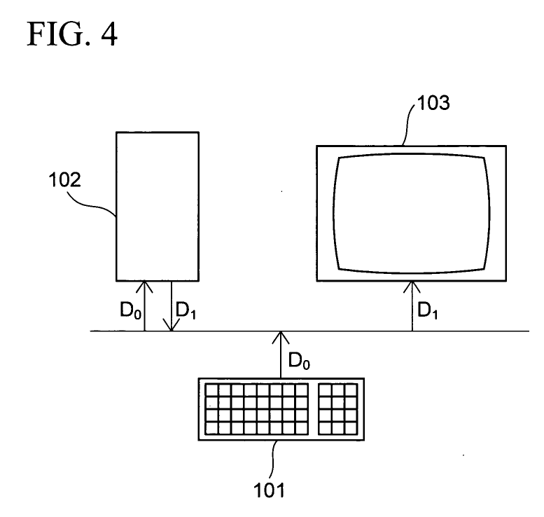

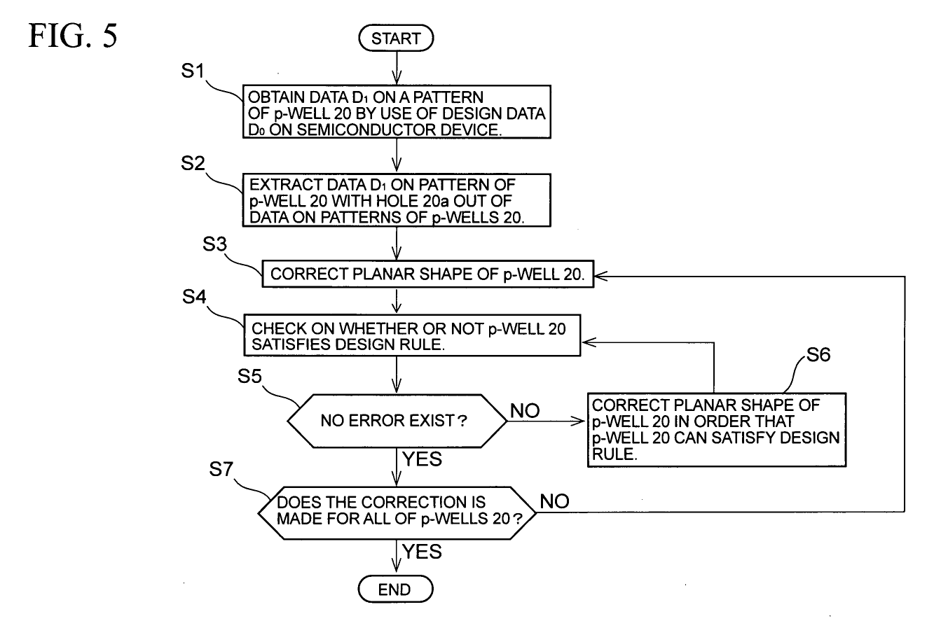

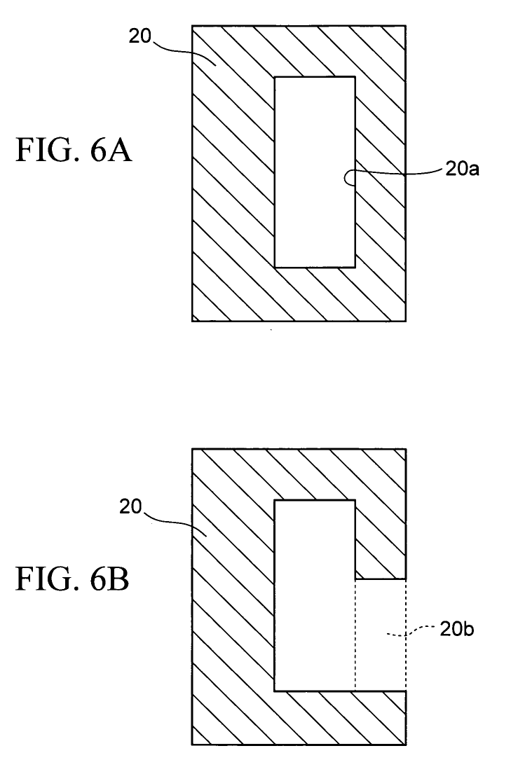

FIG. 4 is a diagram of a configuration of a semiconductor-device designing system used in the present embodiment. FIG. 5 is a flowchart showing a well designing method using this designing system. In addition, FIGS. 6A and 6B are diagrams schematically showing contents processed in accordance with the flowchart shown in FIG. 5.

As shown in FIG. 4, the designing system includes a keyboard 101, a control unit 102 and a monitor 103. The keyboard 101 is used for inputting data D₀ on design of a semiconductor device into the system. The control unit 102 calculates a planar shape of a well on the basis of the data D₀ on the design of the semiconductor device. The monitor 103 displays the planar shape of the well which is calculated by the control unit.

The control unit 102 calculates the planar shape of the well in accordance with the flowchart shown in FIG. 5 in the following manner.

In a first step S1 of FIG. 5, data D₁ on patterns of the p-wells 20 are obtained by use of the data D₀ on the design of the semiconductor device. The data D₁ on the patterns of the p-wells 20 are used for identifying shapes and sizes of the p-wells 20. In this step, no restrictions have been imposed on planar shapes of the p-wells 20. Therefore, it is likely that a hole 20a may be made in the p-well 20 as shown in FIG. 6A, and thus the planar shape of the p-well 20 is made into a ring like form.

In the next step S2 of FIG. 5, data D₁ on the patterns of p-wells having a hole 20a are extracted out of the data D₁ on the patterns of the p-wells 20 to be formed in the silicon substrate.

After step S2 is completed, the process proceeds to step S3.

In step S3, a part 20b of the ring like p-wells is removed as schematically shown in FIG. 6B. By this step, the planar shapes of the p-wells 20 are made into the shape with no hole.

Thereafter, the process proceeds to step S4. In step S4, it is checked on whether or not each of the p-wells 20 which have been obtained in step S3 satisfies the design rule. Such a process is called as design rule check (DRC).

Subsequently, the process proceeds to step S5, where it is checked on whether or not there is an error in the design rule check.

In the case where it is determined that there is an error (NO), the process proceeds to step S6, where the planar shape of the p-well 20 is corrected in order that the planar shape satisfies the design rule.

On the other hand, in the case where it is determined that there is no error (YES), the process proceeds to step S7. Then, it is checked, in step S7, on whether or not all of the patterns of the ring like p-wells 20 have been corrected.

In the case where it is determined, in step S7, that all of the patterns of the ring like p-wells 20 have not been corrected (NO), the process returns to step S3.

On the other hand, in the case where it is determined, in step S7, that all of the patterns of the ring like p-wells 20 have been corrected (YES), the aforementioned series of the process is completed.

According to such a method of designing a well, as shown in the FIG. 6B, the planar shape of the p-well 20 is made into the shape with no hole by cutting away the part 20b of the p-well 20 and connecting the inside of the p-well 20 with the outside of the p-well 20.

According to the p-wells 20 having such a planar shape, the n-well 22 is integrally formed without being separated by the p-wells 20, as described with regard to the first embodiment. This makes it possible to obtain an advantage that no deep n-well is needed for electrically connecting the separated parts of the n-well 22.

The aforementioned method of designing a well can be applied to not only the first embodiment but also a third and a fourth embodiments which will be described later.

(3) Third Embodiment

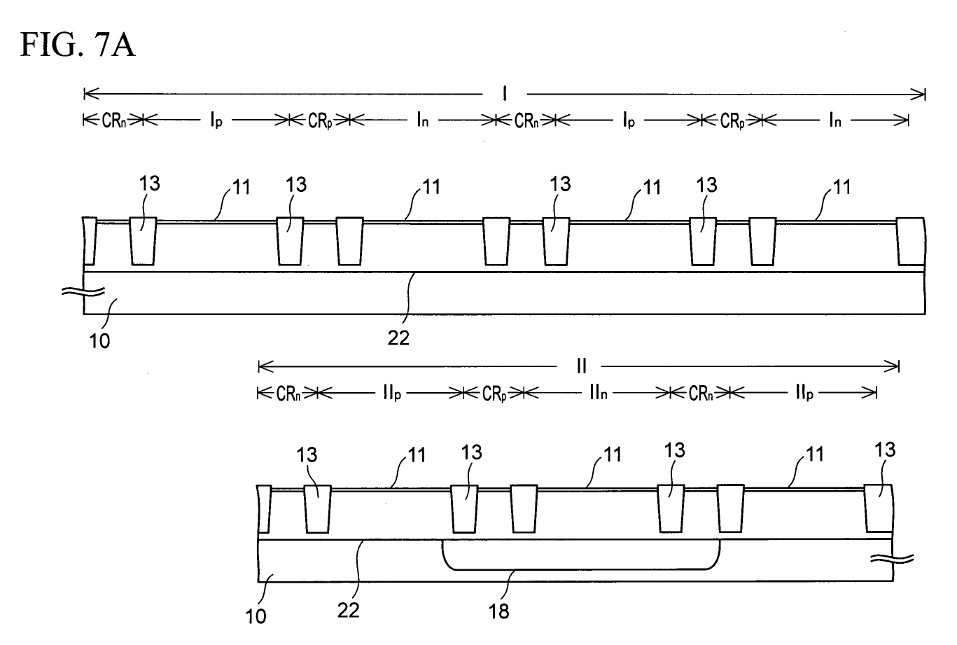

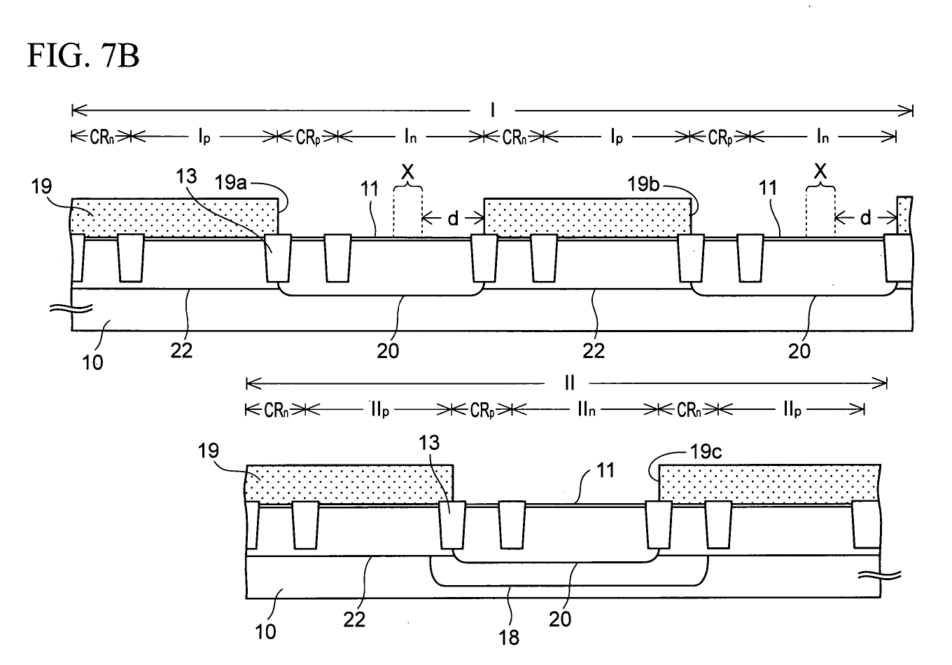

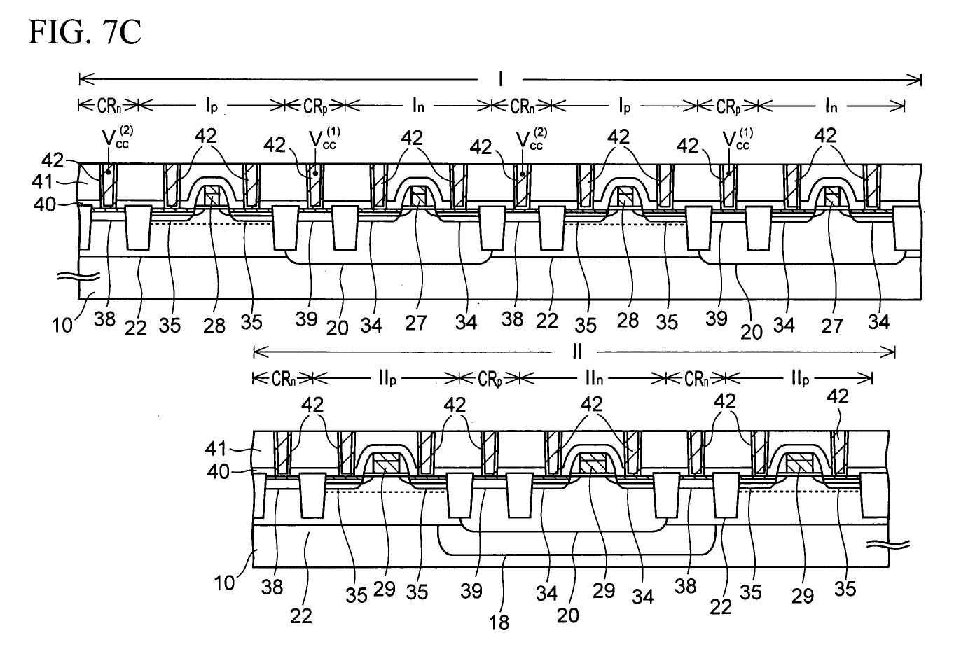

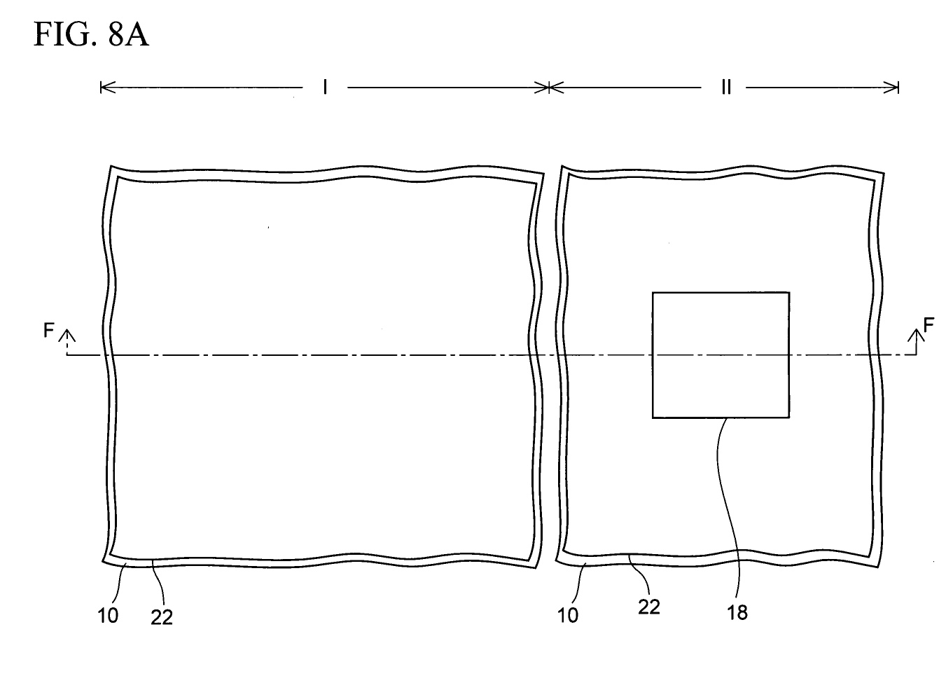

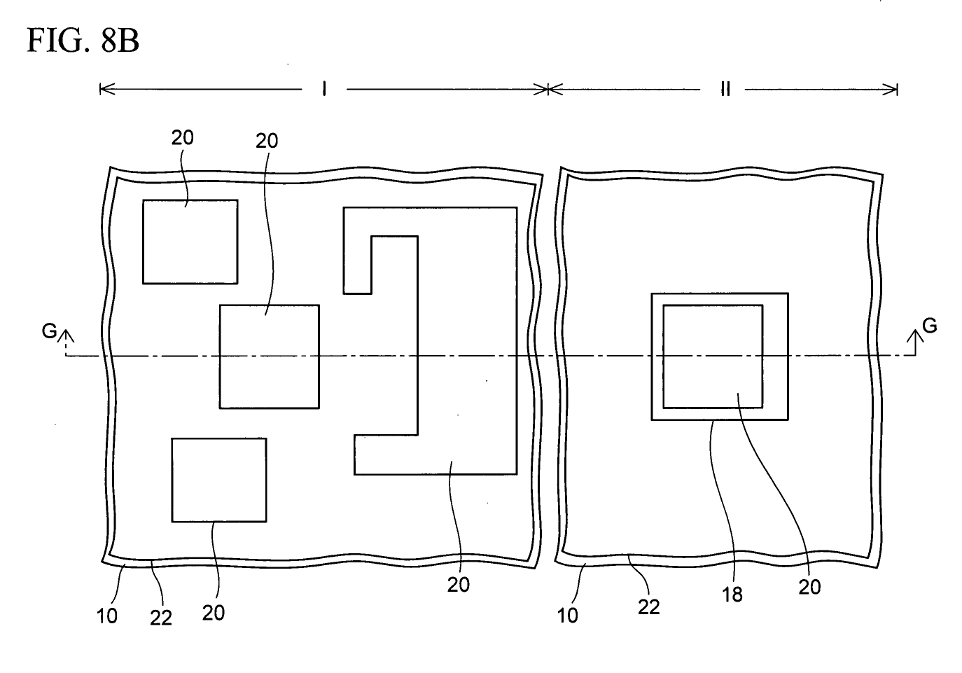

FIGS. 7A to 7C are cross-sectional views of a semiconductor device according to the present embodiment in the process of being manufactured. FIGS. 8A and 8B are plan views of the semiconductor device of the present embodiment. In these figures, the same reference numerals will be used to designate the same components as those in the first embodiment, and their descriptions will be omitted in the following.

In the first embodiment, the n-well 22 is selectively formed only in each of portions of the silicon substrate 10 where the n-well 22 needs to be formed, for example, only in the p-type MOS transistor forming regions Iₚ and IIₚ by means of the ion implantation using the third resist pattern 21 as a mask.

In contrast, the n-well 22 is formed on the entire surface of the silicon substrate 10 in the following manner in the present embodiment.

For the purpose of manufacturing the semiconductor device according to the present embodiment, the steps of the first embodiment which have been described with reference to FIGS. 2A to 2E are firstly performed.

Subsequently, as shown in FIG. 7A, ions of n-type impurities are ion-implanted into the entire surface of the silicon substrate 10, and thus the n-well 22 is formed. In this ion implantation, P⁺ ions are used as the n-type impurities, and acceleration energy of 300 keV and a dose of 3×10¹³ cm⁻² are used as the conditions for the ion implantation.

FIG. 8A is a plan view of the semiconductor device which is obtained by the completion of these steps. FIG. 7A is a cross-sectional view of the semiconductor device taken along the line F-F of FIG. 8A. Incidentally, the thermal oxide film 11 and the element-isolation insulating film 13 are omitted from FIG. 8A for the purpose of making the figure easy to see.

Then, as shown in FIG. 7B, B⁺ ions are ion-implanted into the silicon substrate 10 in the n-type MOS transistor forming regions Iₙ, and IIₙ, as well as the p-type contact regions CRₚ while using the second resist pattern 19 of FIG. 2F used as the mask, and thus p-wells 20 are formed in these region.

The dose for this ion implantation is set to be larger than an amount of implanted p-type impurities needed for compensating the n-type impurities in the n-well 22. For example, the dose is set at 1×10¹⁴ cm ⁻². In addition, the acceleration energy is set at 150 keV, for example.

As explained in the first embodiment, in order to suppress the well-proximity effect, it is preferable that the side surfaces of the resist windows 19a and 19b be kept away from the channel regions X by a sufficient distance d, equal to or greater than 0.4 nm for example.

Thereafter, the second resist pattern 19 is removed.

FIG. 8B is a plan view of the semiconductor device which is obtained by the completion of this ion implantation. FIG. 7B corresponds to a cross-sectional view of the semiconductor device taken along the line G-G of FIG. 8B.

As shown in FIG. 8B, the planar shape of each of the p-wells 20 has no hole as in the case of the first embodiment. Therefore, the n-well 22, which has already been formed, is not separated by the p-wells 20 and accordingly remains formed integrally. As a result, all portions of the n-well 22 are electrically connected with each other.

Thereafter, the steps shown in FIGS. 2H to 2M of the first embodiment are performed, and thus a cross-sectional structure shown in FIG. 7C is obtained.

According to the present embodiment, since the n-well 22 is formed on the entire surface of the silicon substrate 10 as shown in FIG. 7A, the third resist pattern 21 (see FIG. 2G) which is used for selectively forming the n-well 22 in the first embodiment is not needed. Therefore, the process of manufacturing semiconductor devices is curtailed by the step of forming the third resist pattern 21. This makes it possible to lower the manufacturing costs of the semiconductor devices.

In addition, since each of the p-wells 20 is formed to have a planar shape with no hole as shown in the plan view of FIG. 8B, the n-well 22 is not separated by the p-wells 20. Therefore, a deep n-well for electrically connecting the separated n-well 22 is not needed.

In the case of this embodiment, as described with reference to FIG. 7B, the p-wells 20 are formed by ion-implanting the p type impurities into the n-wells 22 in the n-type MOS transistor forming regions Iₙ, and IIₙ once again. Therefore, the n-type impurities, which are unnecessary for operation of the n-type MOS transistors, exist in each of the p-wells 20 along with the p-type impurities.

In general, it is likely that such unnecessary n-type impurities may cause noise in analog elements such as differential amplifiers.

In the present embodiment, however, digital elements which are unlikely to generate noise are formed in the digital circuit region I. For this reason, reliability of the semiconductor device is not deteriorated by noise. In addition, the strict design rule is not applied to the analog circuit region II, unlike the digital circuit region I. Thus, the gate length of each of the third gate electrodes 29 (see FIG. 3C) is designed to be longer than that of each of the first and second gate electrodes 27 and 28. This enhances the noise resistance of the transistors formed in the analog circuit. region II, and makes it possible to prevent the reliability of the semiconductor device from being deteriorated by the aforementioned unnecessary n-type impurities.

(4) Fourth Embodiment

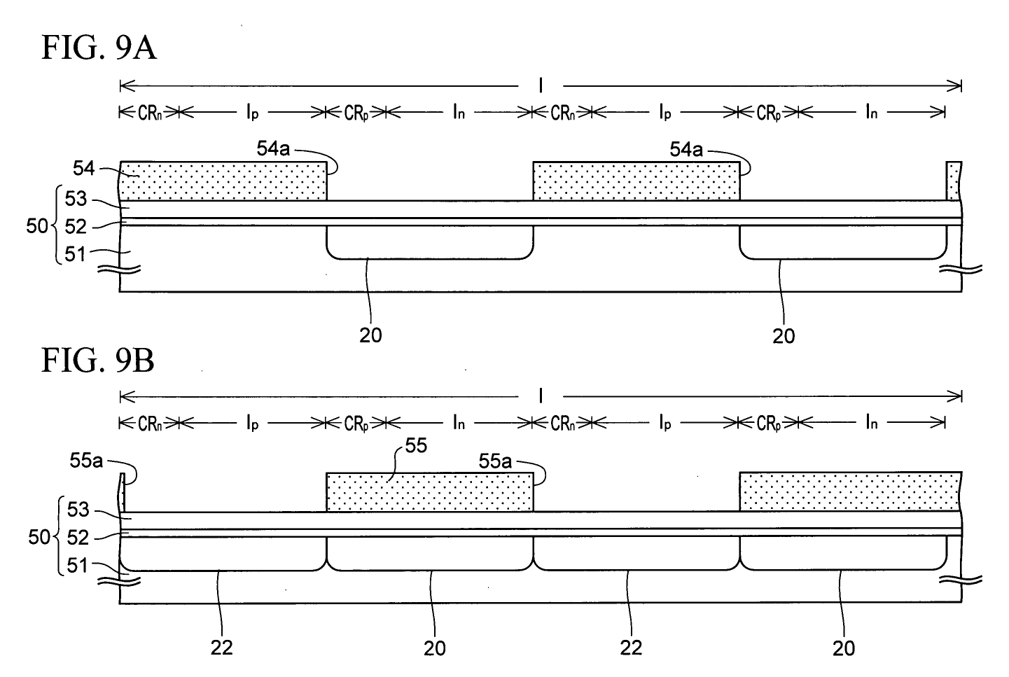

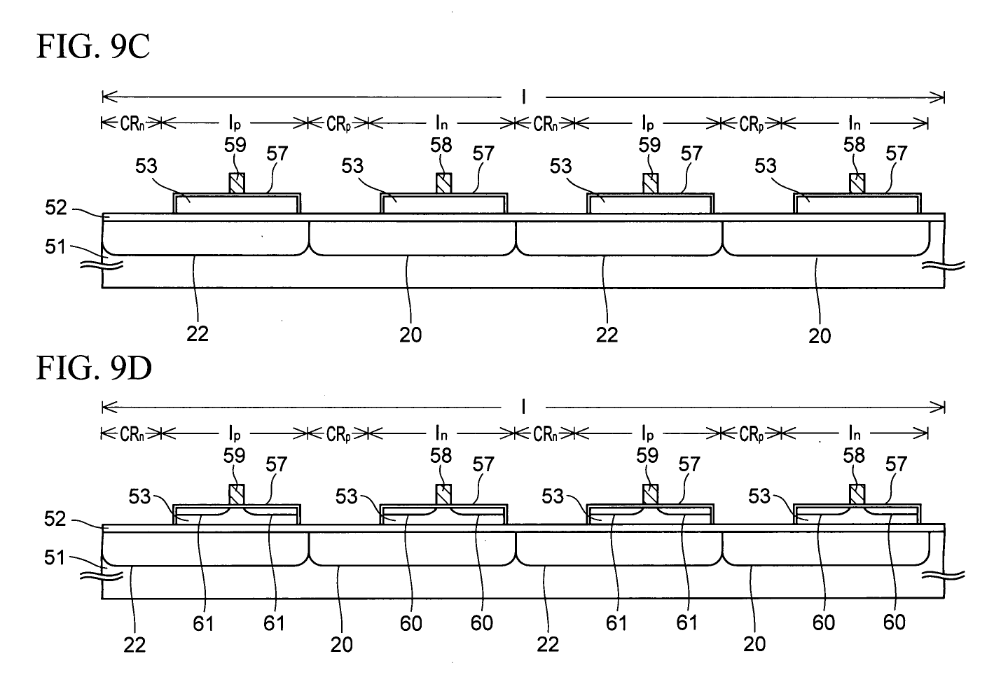

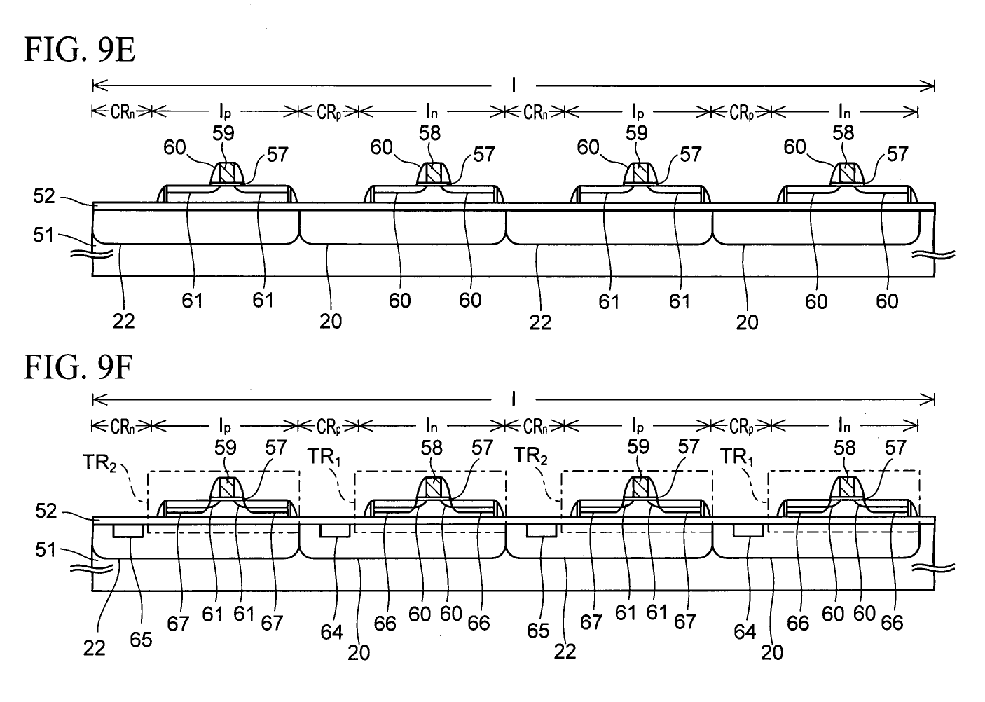

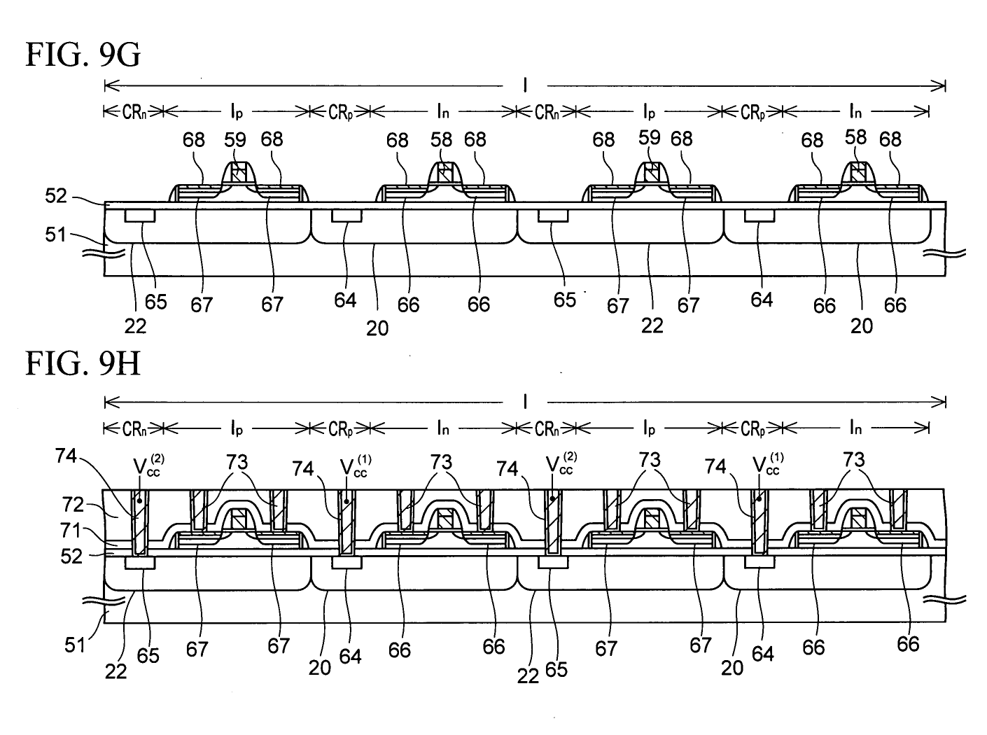

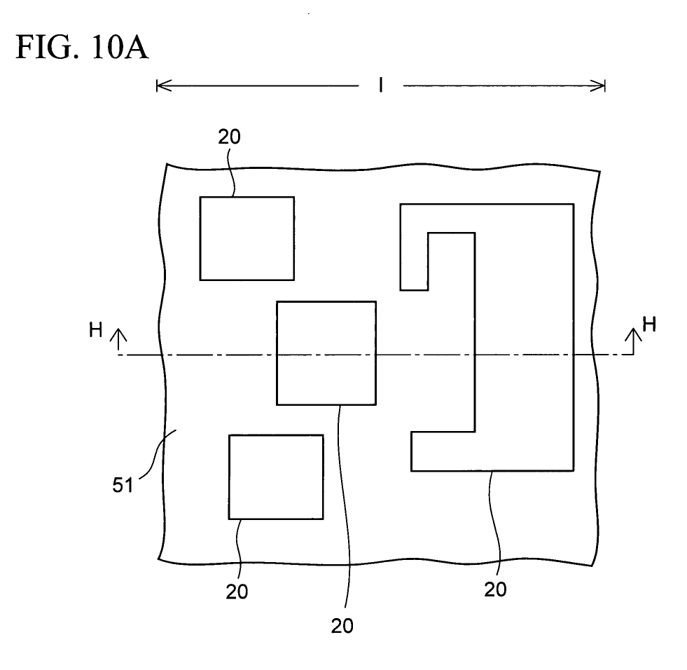

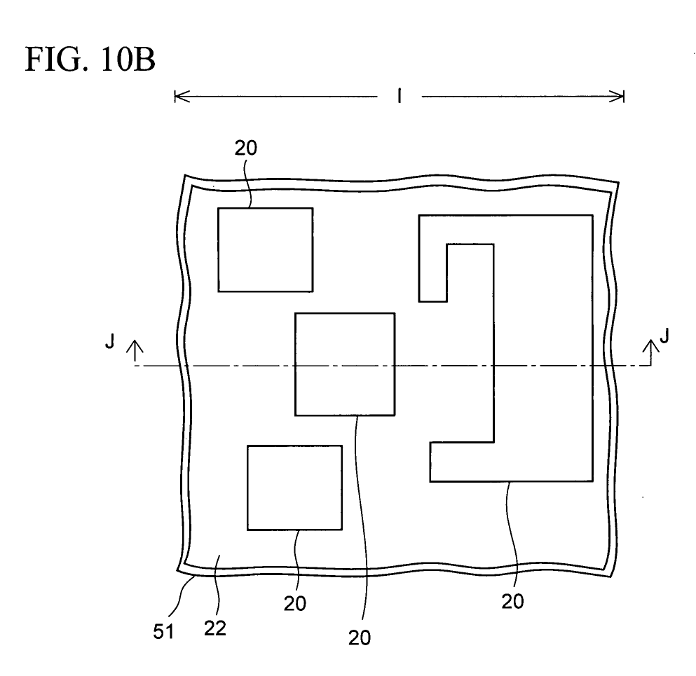

FIGS. 9A to 9H are cross-sectional views of a semiconductor device according to a fourth embodiment of the present invention in the process of being manufactured. FIGS. 10A and 10B are plan views of the semiconductor device of the present embodiment. Incidentally, in these figures, the same reference numerals will be used to designate the same components as those in the first embodiment, and their descriptions will be omitted in the following.

In the present embodiment, a semiconductor device is manufactured by use of a silicon-on-insulator (SOI) substrate.

First, descriptions will be made for steps which are performed until a cross-sectional structure shown in FIG. 9A is obtained.

Firstly, an SOI substrate 50 is formed by laminating a support base 51 made of silicon doped with p-type impurities, an embedded insulating film 52 made of silicon oxide, and a silicon layer 53 in this order by use of Bond-and-Etch Back method. Out of these layers, the silicon layer 53 is approximately 50 nm in thickness, and the embedded insulating layer 52 is approximately 10 nm in thickness.

Next, a photoresist is applied on the SOI substrate 50, and is exposed and developed, thereby forming a first resist pattern 54, which has resist windows 54a on the n-type MOS transistor forming region Iₙ, and p-type contact region CRₚ adjacent the region Iₙ.

Then, B⁺ ions are implanted into the SOI substrate 50 through the resist windows 54a with the following conditions: the acceleration energy of 150 keV and the dose of 3×10¹³ cm⁻². Thus, p-wells 20 are formed in the support base 51. Thereafter, the first resist pattern 54 is removed.

FIG. 10A is a plan view of the semiconductor device which is obtained by the completion of these steps. Aforementioned FIG. 9A corresponds to a cross-sectional view of the semiconductor device taken along the H-H line of FIG. 10A.

As shown in FIG. 10A, each of the p-wells has a planar shape with no hole as in the first embodiment.

Subsequently, as shown in FIG. 9B, a second resist pattern 55, which has resist windows 55a on the p-type MOS transistor forming region Iₚ and n-type contact region CRₙ adjacent to the region Iₚ, is formed on the SOI substrate 50.

Subsequently, n-type impurities, P⁺ ions for example, are ion-implanted into the SOI substrate 50 while using the second resist pattern 55 as the mask, thereby forming the n-well 22 in the support base 51 next to the p-wells 20. No specific restrictions are imposed on conditions for this ion implantation. In the present embodiment, however, the acceleration energy is 300 keV, and the dose is 3×10¹³ cm⁻².

Then, after the second resist pattern 55 is removed, an activation annealing for the SOI substrate 50 is carried out under the substrate temperature of 1000° C. and the process time of 10 seconds. Thus, the impurities in each of the wells 20 and 22 are activated.

Fig. 10B is a plan view of the semiconductor device which is obtained by the completion of these steps. Aforementioned FIG. 9B corresponds to a cross-sectional view of the semiconductor device taken along the line J-J of FIG. l0B.

As shown in Fig. 10B, since the planar shape of each of the p-wells 20 is designed to have no hole, the n-well 22 is not separated by the p-wells 20. Accordingly, the n-well 22 is integrally formed in the SOI substrate 50.

Next, descriptions will be made for steps which are performed until a cross-sectional structure as shown in FIG. 9C is obtained.

First, the silicon layer 53 is patterned, thereby leaving the silicon layer 53 in each of the regions Iₙ, and lₚ like an island. Subsequently, a thermal oxide film with a thickness of approximately 1 nm is formed on the surface of the silicon layer 53. Then, these thermal oxide films are used as gate insulating films 57.

In addition, a polycrystalline silicon film is formed, to a thickness of approximately 100 nm, on each of the gate insulating films 57 and the embedded insulating film 52 by means of the thermal CVD method using silane as the reaction gas. Then, this polycrystalline silicon film is patterned and left as first and second gate electrode 58 and 59 on the wells 20 and 22.

Subsequently, as shown in FIG. 9D, As⁺ ions to serve as n-type impurities are ion-implanted into the silicon layer 53 next to each of the first gate electrodes 58 with the following conditions: the acceleration energy of 5 keV and the dose of 5×10¹⁴ cm⁻². Thus, n-type source/drain extensions 60 are formed.

Subsequently, ions of p-type impurities are ion-implanted into the silicon layer 53 next to each of the second gate electrodes 59, thereby forming p-type source/drain extensions 61. BF₂⁺ ions are used as the p-type impurities for example, and an acceleration energy of 5 keV and a dose of 5×10¹⁴ cm⁻² are used as the conditions for the ion implantation.

Incidentally, the implantation of the p-type impurities and the implantation of the n-type impurities are separately performed by use of the respective resist patterns (not shown). After the ion implantations are completed, the respective resist patterns are removed.

Subsequently, as shown in FIG. 9E, a silicon oxide film is formed, to a thickness of approximately 100 nm, on the entire upper surface of the substrate 51 by means of the thermal CVD method. Then, this silicon oxide film is etched back. Thus, the silicon oxide film is left beside the first and second gate electrodes 58 and 59 as insulating side walls 60.

Next, descriptions will be provided for steps which are performed until the cross-sectional structure as shown in FIG. 9F is obtained.

First, ions of n-type impurities are selectively ion-implanted into the support base 51 in the n-type MOS transistor forming regions Iₙ and the n-type contact regions CRₙ. Thus, n-type source/drain regions 66 are formed in the silicon layer 53 beside the first gate electrodes 58, and n-type impurity diffusion regions 65 for well contact are formed in the support base 51 in the n-type contact regions CRₙ.

In the present embodiment, P⁺ ions are used as the n-type impurities. With regard to conditions for the ion implantation, the acceleration energy is 20 keV, and the dose is 1×10¹⁵ cm⁻².

Furthermore, P⁺ ions to serve as p-type impurities are selectively ion-implanted into the support base 51 in the p-type MOS transistor forming regions Iₚ and the p-type contact regions CRₚ under the following conditions: the acceleration energy of 5 keV and the dose of 1×10¹⁵ cm⁻². Thus, p-type source/drain regions 67 are formed in the silicon layer 53 beside the second gate electrodes 59, and p-type impurity diffusion regions 64 for well contact are formed in the support base 51 in the p-type contact regions CRₚ.

The implantation of the n-type impurities and the implantation of the p-type impurities are separately performed by use of the respective resist patterns (not shown). After the ion implantations are completed, the respective resist patterns are removed.

Performing the steps up to this step, n-type MOS transistors TR₁ are formed respectively in the n-type MOS transistor forming regions Iₙ, and p-type MOS transistors TR₂ are formed respectively in the p-type MOS transistor forming regions Iₚ.

Next, descriptions will be provided for steps which are performed until a cross-sectional structure as shown in FIG. 9G is obtained.

First, a refractory metal layer such as a cobalt layer is formed on the entire upper surface of the support base 51 by means of the spattering method. Thereafter, this refractory metal layer is annealed. Thereby, the silicon of the silicon layer 53 and the refractory metal layer are reacted with each other. Thus, a refractory-metal silicide layer 68 is formed. After that, unreacted refractory metal layer left on the embedded insulating film 52 and the like is removed by wet-etching.

Next, descriptions will be made for steps which are performed until a cross-sectional structure as shown in FIG. 9H is obtained.

First, a silicon nitride film to serve as a cover insulating film 71 is formed to a thickness of approximately 50 nm on the entire upper surface of the support base 51 by means of the plasma CVD method. Subsequently, a silicon oxide film is formed to a thickness of approximately 700 nm on the cover insulating film 71 by means of the HDPCVD method. This silicon oxide film is used as an interlayer dielectric 72. Thereafter, the upper surface of the interlayer dielectric 72 is polished and planarized by means of the CMP method.

Subsequently, each of the cover insulating film 71 and the interlayer dielectric 72 is patterned. Thus, contact holes are formed in the cover insulating film 71 and the interlayer dielectric 72. Thereafter, a titanium film and a titanium nitride film to serve as a glue film are formed, in this order, on the inner surfaces of these contact holes and on the upper surface of the interlayer dielectric 72 by means of the spattering method. Then, a tungsten film is formed on this glue film by means of the CVD method. Thus, the contact holes are fully buried with this tungsten film. Thereafter, excessive portions of the tungsten film and the glue film on the interlayer dielectric 72 are polished and removed by means of the CMP method. Thus, the tungsten film and the glue film are left only in the contact holes as first and second conductive plugs 73 and 74.

Out of these conductive plugs, the first conductive plugs 73 are used for applying a voltage to the respective source/drain regions 66 and 67 of the transistors.

On the other hand, the second conductive plugs 74 are electrically connected with the p-type impurity diffusion regions 64 for well contact, and are used to apply first substrate bias voltage Vcc⁽¹⁾ to the p-wells 20 and second substrate bias voltage Vcc⁽²⁾ to the n-well 20.

A basic structure of the semiconductor device according to the present embodiment has been completed in the aforementioned manner.

In the present embodiment, the substrate bias voltages Vcc⁽¹⁾ and Vcc⁽²⁾ are applied to the p-wells 20 and n-wells 22 under the gate electrodes 58 and 59 respectively through the second conductive plugs 74 shown in FIG. 9H, and a voltage between the substrate and each of the gate electrodes is controlled by the substrate bias voltages.

Such functions performed respectively by the wells 20 and 22 are similar to those performed by the back gates disclosed in Japanese Patent Laid-open Official Gazette No. Sho. 62-277747. In the case of this embodiment, however, the functions performed by the back gates are assigned respectively to the wells 20 and the well 22, so that fine back gates need not be formed by patterning the silicon layer 53. For this reason, the present embodiment makes it unnecessary to perform a complicated step of forming fine back gates. Accordingly, costs for manufacturing the semiconductor devices can be lowered in comparison with Japanese Patent Laid-open Official Gazette No. Sho. 62-277747.

Furthermore, as described with reference to FIG. 10B, each of the p-wells 20 is designed to have a planar shape with no hole. Therefore, the n-well 22 is not separated by the p-wells 20. Accordingly, a deep n-well for connecting separated parts of p-wells 20 need not be formed in the support base 51.

Moreover, the resistance of the n-well 22 can be lowered than that of the deep n-well for the same reason in the first embodiment. In the case where, for example, the SOI substrate 50 is used as in the present embodiment, the sheet resistance of the deep n-well becomes approximately 1000 Ω/, whereas the sheet resistance of the n-well 22 is approximately 150 Ω/. Thus, the resistance of the n-well 22 can be significantly lowered. Accordingly, it is made possible to prevent the electric potential of the n-well 22 from varying from one position to another due to a voltage drop, and to prevent individual differences in property from occurring among the plurality of p-type MOS transistors TR₂.

Here, both the doses of the p-wells 20 and the dose of the n-well 22 are 3×10¹³ cm⁻² in the aforementioned case. However, p-wells 20 and the n-well 22 may be made into p⁺-wells and an n⁺-well respectively by increasing the dose than the above. By forming p⁺-wells and an n⁺-well in this manner, resistance of the wells 20 and 22 is lowered, which is advantageous for fast operation of the semiconductor device. In the case where, for example, a deep n-well is formed in the SOI substrate 50, the sheet resistance of the deep n-well becomes typically 1.3 kΩ/. However, the sheet resistance of the aforementioned n⁺-well becomes approximately 90 Ω/. Hence, the increased dose enables the n-well 22 to have a lower resistance which is seven hundredths of the sheet resistance of the deep n-well.

On the other hand, if the wells 20 and the well 22 are formed by means of the dose of approximately 3×10¹³ cm⁻² as in the case of the present embodiment, it is made possible to shorten the process time of the ion-implantation for these wells. This brings about an advantage that throughput of the manufacturing process can be increased.

In the case of the p-type silicon substrate 10 for general-purpose as used in the first embodiment, the initial dose of p-type impurities in the substrate is not so large, and the sheet resistance of the substrate in the initial condition is as relatively high as approximately 10 Ω/. The reason for this is that the general-purpose p-type silicon substrate 10 is designed to enable the n-well 22 to be formed without an extraordinarily large dose of n-type impurities.

In contrast, in the case of the SOI substrate 50 which is used in this embodiment, the support base 51 may be caused to have a lower resistance by means of doping the support base 51 with high concentration p-type impurities in advance. This is because, in general, no impurity diffusion region such as a well is formed in the support base 51.

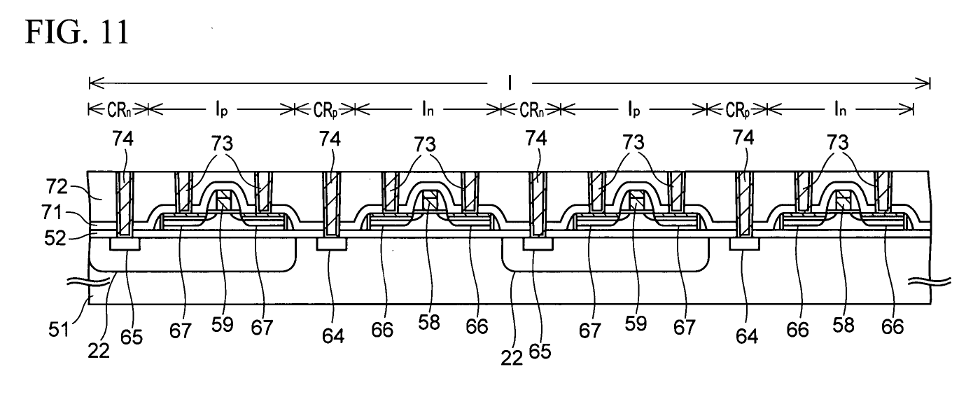

An even electric potential can be given to the support base 51 by means of causing the support base 51 to have a lower resistance in this manner, even if the p-wells 20 are eliminated. FIG. 11 shows a cross-sectional view of a semiconductor device in which p-wells 20 are eliminated.

If the p-wells 20 are eliminated as shown in FIG. 11, the process of manufacturing semiconductor devices can be shortened by the step of forming the p-wells 20. This makes it possible to lower the cost for manufacturing the semiconductor device.

According to the present invention, as described above, the first conduction type well is formed in a way that the inside surrounded by the outline has the integrated planar shape, and the second conduction type well is formed to have the planar shape which is obtained by inverting the pattern of the first conduction type well. Therefore, the second conduction type well is not separated by the first conduction type well. This makes it unnecessary to form a deep well for connecting the separated parts of the second conduction type well. Accordingly, the present invention makes it possible to suppress the well-proximity effect which conspicuously occurs when the deep well is formed. Thus, the present invention enables the threshold voltage of each of the MOS transistors to be prevented from varying due to this well-proximity effect. Consequently, the present invention makes it possible to provide highly reliable semiconductor devices.

What is claimed is:

1. A semiconductor device comprising:
a semiconductor substrate of a first conduction type;
a first conduction type well formed in the semiconductor substrate, where an inside of an outline of the first conduction type well being integral planar shape;
a second conduction type well formed in the semiconductor substrate and having an integral planar shape obtained by inverting a planar shape of the first conduction type well;
a first and a second gate electrodes formed on the first and second conduction type wells respectively with a gate insulating film interposed therebetween;
a second conduction type source/drain region formed in the first conduction type well beside the first gate electrode;
a first conduction type impurity diffusion region for well contact, which is formed at a distance from the second conduction type source/drain region in the first conductive type well and is to be applied with a first substrate bias voltage;
a first conduction type source/drain region formed in the second conduction type well beside the second gate electrode;
a second conduction type impurity diffusion region for well contact, which is formed at a distance from the first conduction type source/drain region in the second conduction type well and is to be applied with a second substrate bias voltage.

2. The semiconductor device according to claim 1, wherein the first conduction type well is formed by introducing first and second conduction type impurities into the semiconductor substrate, where an amount of the first conduction type impurities is greater than required for compensating the second conduction type impurities.

3. The semiconductor device according to claim 1, wherein the first and second conduction type wells are formed in a digital circuit region of the semiconductor substrate.

4. The semiconductor device according to claim 3, wherein the semiconductor substrate has an analog circuit region at a portion other than the digital circuit region.

5. The semiconductor device according to claim 4, wherein a triple-well structure is formed in the analog circuit region of the semiconductor substrate, and a third gate electrode whose gate length is longer than those of the first and the second gate electrodes is formed on the triple-well structure with a gate insulating film interposed therebetween.

6. A semiconductor device comprising:
a silicon-on-insulator substrate formed by sequentially laminating a first conduction type support base, an embedded insulating film, and a silicon layer;
a fist conduction type impurity diffusion region for well contact which is formed in the support base and is to be applied with a first substrate bias voltage;
a second conduction type well formed at a distance from the fist conduction type impurity diffusion region in the support base and having a integral planar shape;
a second conduction type impurity diffusion region for well contact which is formed in the second conduction type well and is to be applied with a second a second substrate bias voltage;
a first gate electrode, formed on a region of the silicon layer where the second conduction type well is not formed, with a gate insulating film interposed therebetween;
a second gate electrode formed on the silicon layer located over the second conduction type well with a gate insulating film interposed therebetween;
a second conduction type source/drain region formed in the silicon layer beside the first gate electrode; and
a first conduction type source/drain region formed in the silicon layer beside the second gate electrode.

7. The semiconductor device according to claim 6, wherein a first conduction type well is formed in a region of the support base where the second conduction type well is not formed, where the first conduction type well having a planar shape of an inverted pattern of the second conduction type well and having no hole.

8. The semiconductor device according to claim 7, wherein a planar shape of the silicon layer is formed like an island over the first and second conduction type wells.

9. A method of manufacturing a semiconductor device comprising the steps of:
forming a first conduction type well by introducing a first conduction type impurities into a partial region of the first conduction type semiconductor substrate, where an inside of an outline of the first conduction type well being integral planar shape;
forming a second conduction type well, which has an integral planar shape obtained by inverting a planar shape of the first conduction type well, by introducing a second conduction type impurities into the semiconductor substrate;
forming first and second gate electrodes on the first and second conduction type wells respectively with a gate insulating film interposed therebetween;
forming a second conduction type source/drain region in the first conduction type well beside the first gate electrode;
forming a first conduction type impurity diffusion region for well contact formed at a distance from the second conduction type source/drain region in a portion of the first conduction type well;
forming a first conduction type source/drain region in the second conduction type well beside the second gate electrode; and
forming an second conduction type impurity diffusion region for well contact in a portion of the second conduction type well which is located at a distance from the first conduction type source/drain region.

10. The method of manufacturing a semiconductor device according to claim 9,
wherein, in the step of forming the second conduction type well, the impurities of the second conduction type are introduced into an entire surface of the semiconductor substrate, and
in the step of forming the first conduction type well, the impurities of the first conduction type are introduced into the partial region of the semiconductor substrate with an amount that is greater than required for compensating the second conduction type impurities.

11. The method of manufacturing a semiconductor device according to claim 9, wherein the step of forming the first conduction type well comprises the steps of:
forming, on the semiconductor substrate, a resist pattern having a resist window formed away from a MOS transistor channel region by 0.4 μm or more; and
ion-implanting the first conduction type impurities into the silicon substrate through the resist window.

12. The method of manufacturing a semiconductor device according to claim 9, wherein the step of forming the second conduction type well comprises the steps of:
forming, on the semiconductor substrate, a resist pattern having a resist window formed away from a MOS transistor channel region by 0.4 μm or more; and
ion-implanting the second conduction type impurities into the semiconductor substrate through the resist window.

13. A method of manufacturing a semiconductor device comprising the steps of:
forming a second conduction type well having a integral planar shape by introducing second conduction type impurities into a partial region of a silicon-on-insulator substrate made by sequentially laminating a first conduction type support base, an embedded insulating film, and a silicon layer;
forming a first gate electrode, on a region of the silicon layer where the second conduction type well is not formed, with an gate insulating film interposed therebetween, and forming a second gate electrode on the silicon layer over the second conduction type well with an gate insulating film interposed therebetween;
forming a second conduction type source/drain region in the silicon layer beside the first gate electrode;
forming a second conduction type impurity diffusion region for well contact in the second conduction type well;
forming a first conduction type source/drain region in the silicon layer beside the second gate electrode; and
forming a first conduction type impurity diffusion region for well contact in a portion of the support base which is located at a distance from the second conduction type well.

14. The method of manufacturing a semiconductor device according to claim 13, further comprising a step of:
forming a first conduction type well, which has a planer shape obtained by inverting a planar shape of the second conduction type well and has no hole, by introducing first conduction type impurities into a region of the support base where the second conduction type well is not formed.

15. The method of manufacturing a semiconductor device according to claim 9, wherein the first conduction type well is designed by use of a well designing method comprising the steps of:
extracting data on a pattern of the first conduction type well having a planar shape with a hole, out of data on patterns of a plurality of the first conduction type wells; and
making the planar shape of the first conduction type well into a shape having no hole by correcting the extracted data on the pattern of the well of the first conduction type.

16. The method of manufacturing a semiconductor device according to claim 14, wherein the first conduction type well is designed by use of a well designing method comprising the steps of:
extracting data on a pattern of the first conduction type well having a planar shape with a hole, out of data on patterns of a plurality of the first conduction type wells; and
making the planar shape of the first conduction type well into a shape having no hole by correcting the extracted data on the pattern of the well of the first conduction type.
